(19) United States
(12) Patent Application Publication
(10) Pub. No.: US 2011/0086315 A1
(43) Pub. Date: Apr. 14, 2011

(54) EXPOSURE APPARATUS, EXPOSURE METHOD, AND DEVICE MANUFACTURING METHOD

(75) Inventor: Go ICHINOSE, Fukaya-shi (JP)

(73) Assignee: NIKON CORPORATION, TOKYO (JP)

(21) Appl. No.: 12/893,053

(22) Filed: Sep. 29, 2010

Related U.S. Application Data
(60) Provisional application No. 61/247,133, filed on Sep. 30, 2009.

(51) Int. Cl. G03F 7/20; G21G 5/00; G01B 11/14

(52) U.S. Cl. 430/325; 250/491.1; 356/615; 356/620; 250/492.2

(57) ABSTRACT

A first driving section and a second driving section apply a drive farce in an X-axis direction, a Y-axis direction, a Z-axis direction, and a θx direction, respectively, with respect to one end and the other end of a fine movement stage whose one end and the other end in the Y-axis direction are each supported, so that the fine movement stage is relatively movable with respect to a coarse movement stage within an XY plane. Accordingly, by the first and the second driving sections making drive forces in directions opposite to each other in a θx direction apply simultaneously to one end and the other end of the fine movement stage (refer to the black arrow in the drawing), the fine movement stage (and the wafer held by the stage) can be deformed to a concave shape or a convex shape within a YZ plane.

### CROSS-REFERENCE TO RELATED APPLICATIONS

This non-provisional application claims the benefit of Provisional Application No. 61/247,133 filed Sep. 30, 2009, the disclosure of which is hereby incorporated herein by reference in its entirety.

### BACKGROUND OF THE INVENTION

1. Field of the Invention

The present invention relates to exposure apparatuses, exposure methods, and device manufacturing methods, and more particularly to an exposure apparatus and an exposure method in which an object is exposed with an energy beam via an optical system, and a device manufacturing method which uses the exposure apparatus or the exposure method.

2. Description of the Background Art

Conventionally, in a lithography process for manufacturing electron devices (microdevices) such as semiconductor devices (integrated circuits or the like) or liquid crystal display elements, an exposure apparatus such as a projection exposure apparatus by a step-and-repeat method (a so-called stepper) or a projection exposure apparatus by a step-and-scan method (a so-called scanning stepper (which is also called a scanner)) is mainly used.

Substrates such as a wafer, a glass plate or the like subject to exposure which are used in these types of exposure apparatuses are gradually (for example, in the case of a wafer, in every ten years) becoming larger. Although a 300-mm wafer which has a diameter of 300 mm is currently the mainstream, the coming of age of a 450 mm wafer which has a diameter of 450 mm looms near. When the transition to 450 mm wafers occurs, the number of dies (chips) output from a single wafer becomes double or more the number of chips from the current 300 mm wafer, which contributes to reducing the cost. In addition, it is expected that through efficient use of energy, water, and other resources, cost of all resource use will be reduced.

However, with the wafer size increasing, the size and the weight of the wafer stage which moves holding the wafer will also increase. Increasing weight of the wafer stage can easily degrade the position control performance of the wafer stage, especially in the case of a scanner which performs exposure (transfer of a reticle pattern) during a synchronous movement of a reticle stage and a wafer stage as is disclosed in, for example, U.S. Pat. No. 5,646,413, whereas, increasing size of the wafer stage will increase the footprint of the apparatus. Therefore, it is desirable to make the size and the weight of a movable member which moves holding a wafer be thin and light. However, because the thickness of the wafer does not increase in proportion to the size of the wafer, intensity of the 450 mm wafer is much weaker when compared to the 300 mm wafer. Therefore, in the case of making the movable member thin, there was a concern of the movable member deforming by the weight of the wafer and the movable member itself, and as a consequence, the wafer held by the movable member could also be deformed, which would degrade the transfer accuracy of the pattern to the wafer.

### SUMMARY OF THE INVENTION

According to a first aspect of the present invention, there is provided a first exposure apparatus that exposes an object with an energy beam via an optical system supported by a first support member, the apparatus comprising: a first movable member which holds the object and is movable along a predetermined plane including at least a first and second axis that are orthogonal to each other; a second movable member which supports one end and the other end of the first movable member in a direction parallel to the second axis and is movable at least along the predetermined plane; a guide surface forming member which forms a guide surface used when the first movable member moves along the predetermined plane; a second support member which is placed apart from the guide surface forming member on a side opposite to the optical system, via the guide surface forming member, and whose positional relation with the first support member is maintained at a predetermined state; a position measuring system which includes a first measurement member that irradiates a measurement surface parallel to the predetermined plane with a measurement beam and receives light from the measurement surface, and which obtains positional information of the first movable member within the predetermined plane based on an output of the first measurement member, the measurement surface being arranged at one of the first movable member and the second support member and at least a part of the first measurement member being arranged at the other of the first movable member and the second support member; and a drive system which includes a first driving section which applies a drive force on the one end of the first movable member and a second driving section that applies a drive force on the other end, and drives the first movable member in one of a singly driven and integrally driven manner with the second movable member, based on positional information from the position measuring system, whereby the first and second driving sections can apply a drive force whose magnitude and a direction of generation can each be controlled independently to the one end and the other end of the first movable member, in a direction parallel to the first axis and the second axis, a direction orthogonal to the predetermined plane, and a rotational direction around an axis parallel to the first axis.

According to this apparatus, the first and second driving sections of the drive system relatively drive one end and the other end in a direction parallel to the second axis of the first movable member holding the object, respectively, with respect to the second movable member which supports the fist movable member. Accordingly, by applying drive forces in directions opposite to each other in a rotational direction around the axis parallel to the first axis to the one end and the other end of the first movable member, the first movable member can be deflected in a convexo-concave shape when viewing the first movable member from the first-axis direction.

In this case, the guide surface is used to guide the movable body in a direction orthogonal to the predetermined plane and can be of a contact type or a noncontact type. For example, the guide method of the noncontact type includes a configuration using static gas bearings such as air pads, a configuration using magnetic levitation, and the like. Further, the guide surface is not limited to a configuration in which the movable body is guided following the shape of the guide surface. For example, in the configuration using static gas bearings such as air pads, the opposed surface of the guide surface forming member that is opposed to the movable body is finished so as to have a high flatness degree and the movable body is guided in a noncontact manner via a predetermined gap so as to follow the shape of the opposed surface. On the other hand, in the configuration in which while a part of a motor or the like that uses an electromagnetic force is placed at the guide surface forming member, a part of the motor or the like is placed also at the movable body, and a force acting in a direction orthogonal to the predetermined plane described above is generated by the guide surface forming member and the movable body cooperating, the position of the movable body is controlled by the force on a predetermined plane. For example, a configuration is also included in which a planar motor is arranged at the guide surface forming member and forces in directions which include two directions orthogonal to each other within the predetermined plane and the direction orthogonal to the predetermined plane are made to be generated on the movable body and the movable body is levitated in a noncontact manner without arranging the static gas bearings.

According to a second aspect of the present invention, there is provided a second exposure apparatus that exposes an object with an energy beam via an optical system supported by a first support member, the apparatus comprising: a movable body that holds the object and is movable along a predetermined plane; a second support member whose positional relation with the first support member is maintained in a predetermined state; a movable body supporting member placed between the optical system and the second support member so as to be apart from the second support member, which supports the movable body at one end and the other end of the movable body in a direction orthogonal to a longitudinal direction of the second support member when the movable body moves along the predetermined plane; a position measuring system which includes a first measurement member that irradiates a measurement surface parallel to the predetermined plane with a measurement beam and receives light from the measurement surface, and which obtains positional information of the movable body within the predetermined plane based on an output of the first measurement member, the measurement surface being arranged at one of the movable body and the second support member and at least a part of the first measurement member being arranged at the other of the movable body and the second support member; and a drive system which includes a first driving section that applies a drive force on the one end of the movable body and a second driving section that applies a drive force on the other end of the movable body, and relatively drives the movable body with respect to the movable body support member, based on positional information from the position measuring system.

According to this apparatus, the first and second driving sections of the drive system relatively drive one end and the other end of the movable body holding the object in the direction orthogonal to the longitudinal direction of the second support member, respectively. Accordingly, by applying drive forces in directions opposite to each other in a rotational direction around the axis parallel to the longitudinal direction of the second support member to the one end and the other end of the movable body, the movable body can be deflected in a convexo-concave shape when viewed from the axial direction parallel to the longitudinal direction of the second support member.

In this case, the movable body supporting member supporting the movable body at least in two points in the direction orthogonal to the longitudinal direction of the second support member means that the movable body is supported in the direction orthogonal to the longitudinal direction of the second support member, for example, at only both ends or at both ends and a mid section in the direction orthogonal to the two-dimensional plane, at a section excluding the center and both ends in the direction orthogonal to the longitudinal direction of the second support member, the entire section including both ends in the direction orthogonal to the longitudinal direction of the second support member, or the like. In this case, the method of the support widely includes the contact support, as a matter of course, and the noncontact support such as the support via static gas bearings such as air pads or the magnetic levitation or the like.

According to a third aspect of the present invention, there is provided a device manufacturing method, including exposing an object with one of the first and second exposure apparatus of the present invention; and developing the object which has been exposed.

According to a fourth aspect of the present invention, there is provided an exposure method in which an object is exposed with an energy beam via an optical system supported by a first support member, the method comprising: making a first movable member, which holds the object and is movable along a predetermined plane including at least a first and second axis that are orthogonal to each other, relatively drivable at one end and the other end of the first movable member in a direction parallel to the second axis, be supported by a second movable member which is movable at least along the predetermined plane; irradiating a measurement beam on a measurement plane parallel to the predetermined plane provided on one of the first movable member and the second support member, which is placed away from a guide surface forming member that forms a guide surface when the first movable member moves along the predetermined plane on the opposite side of the optical system, with the guide surface forming member in between, and whose positional relation with the first support member is maintained at a predetermined state, and obtaining positional information at least within the predetermined plane of the first movable member, based on an output of a first measurement member which receives light from the measurement plane and has at least a part of the member provided in the other of the first movable member and the second support member; and applying a drive force whose magnitude and a direction of generation can each be controlled independently to the one end and the other end of the first movable member, in a direction parallel to the first axis and the second axis, a direction orthogonal to the predetermined plane, and a rotational direction around an axis parallel to the first axis, based on positional information which has been obtained.

According to this method, one end and the other end in a direction parallel to the second axis of the first movable member holding the object are driven, respectively, with respect to the second movable member which supports the first movable member. Accordingly, by applying drive forces in directions opposite to each other in a rotational direction around the axis parallel to the first axis to the one end and the other end of the first movable member, the first movable member can be deflected in a convexo-concave shape when viewing the first movable member from the first-axis direction.

According to a fifth aspect of the present invention, there is provided device manufacturing method, including exposing an object by the exposure method of the present invention; and developing the object which has been exposed.

### BRIEF DESCRIPTION OF THE DRAWINGS

In the accompanying drawings;

FIG. 1 is a view schematically showing a configuration of an exposure apparatus of an embodiment;

FIG. 2 is a plan view of the exposure apparatus of FIG. 1;

FIG. 3 is a side view of the exposure apparatus of FIG. 1 when viewed from the +Y side;

FIG. 4A is a plan view of a wafer stage WST1 which the exposure apparatus is equipped with, FIG. 4B is an end view of the cross section taken along the line B-B of FIG. 4A, and FIG. 4C is an end view of the cross section taken along the line C-C of FIG. 4A;

FIG. 5 is a perspective view showing a configuration of a fine movement stage configuring a part of the stage device in FIGS. 4A to 4C;

FIG. 6 is a planar view showing a placement of a magnet unit and a coil unit that structure a fine movement stage drive system;

FIG. 7A is a side view showing a placement of a magnet unit and a coil unit that structure a fine movement stage drive system when viewed from the +X direction, and FIG. 7B is a side view showing a placement of a magnet unit and a coil unit that structure a fine movement stage drive system when viewed from the −Y direction;

FIG. 8A is a view used to explain a drive principle when a fine movement stage is driven in the X-axis direction, FIG. 8B is a view used to explain a drive principle when a fine movement stage is driven in the Z-axis direction, and FIG. 8C is a view used to explain a drive principle when a fine movement stage is driven in the Y-axis direction;

FIG. 9A is a view used to explain an operation when a fine movement stage is rotated around the Z-axis with respect to a coarse movement stage, FIG. 9B is a view used to explain an operation when a fine movement stage is rotated around the X-axis with respect to a coarse movement stage, and FIG. 9C is a view used to explain an operation when a fine movement stage is rotated around the Y-axis with respect to a coarse movement stage;

FIG. 10 is a view used to explain an operation when a center section of the fine movement stage is deflected in the +Z direction;

FIG. 11 is a view showing a configuration of a fine movement stage position measuring system;

FIG. 12 is a planar view showing a placement of an encoder head and a scale configuring a relative stage position measuring system;

FIG. 13 is a block diagram used to explain an input/output relation of a main controller equipped in the exposure apparatus in FIG. 1;

FIG. 14 is a view showing a state where exposure is performed on a wafer placed on wafer stage WST1, and wafer exchange is performed on wafer stage WST2;

FIG. 15 is a view showing a state where exposure is performed on a wafer mounted on wafer stage WST1 and wafer alignment is performed to a wafer mounted on wafer stage WST2;

FIG. 16 is a view showing a state where wafer stage WST2 moves toward a right-side scrum position on a surface plate 14B;

FIG. 17 is a view showing a state where movement of wafer stage WST1 and wafer stage WST2 to the scrum position is completed; and

FIG. 18 is a view showing a state where exposure is performed on a wafer mounted on wafer stage WST2 and wafer exchange is performed on wafer stage WST1.

### DESCRIPTION OF THE EMBODIMENTS

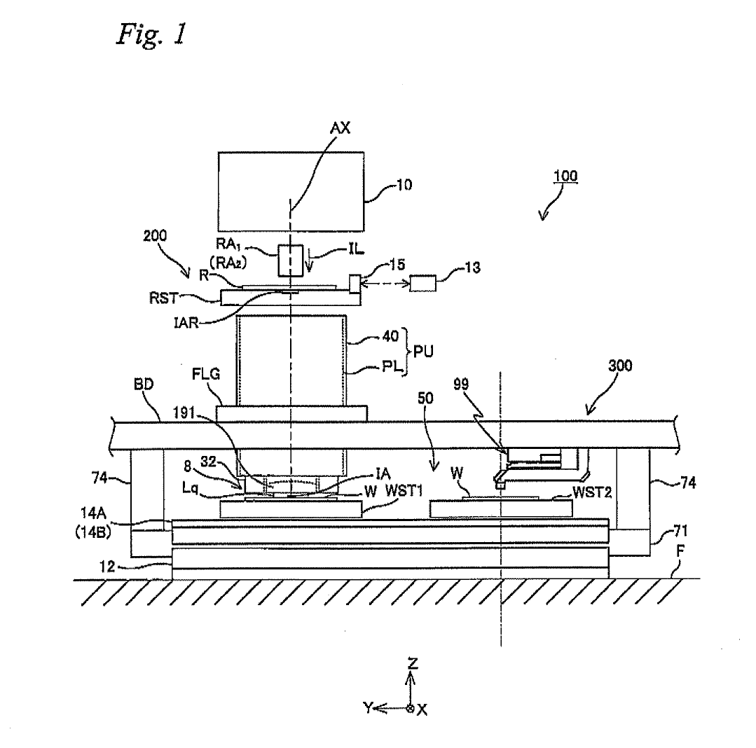

An embodiment of the present invention will be described below, with reference to FIGS. 1 to 18.

FIG. 1 schematically shows a configuration of an exposure apparatus 100 related to the embodiment. Exposure apparatus 100 is a projection exposure apparatus by a step-and-scan method, which is a so-called scanner. As described later on, a projection optical system PL is provided in the present embodiment, and in the description below, the explanation is given assuming that a direction parallel to an optical axis AX of projection optical system PL is a Z-axis direction, a direction in which a reticle and a wafer are relatively scanned within a plane orthogonal to the Z-axis direction is a Y-axis direction, and a direction orthogonal to the Z-axis and the Y-axis is an X-axis direction, and rotational (tilt) directions around the X-axis, Y-axis and Z-axis are θx, θy and θz directions, respectively.

As shown in FIG. 1, exposure apparatus 100 is equipped with an exposure station (exposure processing section) 200 placed in the vicinity of the +Y side end on a base board 12, a measurement station (measurement processing section) 300 placed in the vicinity of the −Y side end on base board 12, a stage device 50 that includes two wafer stages WST1 and WST2, their control system and the like. In FIG. 1, wafer stage WST1 is located in exposure station 200 and a wafer W is held on wafer stage WST1. And, wafer stage WST2 is located in measurement station 300 and another wafer W is held on wafer stage WST2.

Exposure station 200 is equipped with an illuminations system 10, a reticle stage RST, a projection unit PU, a local liquid immersion device 8, and the like.

Illumination system 10 includes: a light source; and an illumination optical system that has an illuminance uniformity optical system including an optical integrator and the like, and a reticle blind and the like (none of which are illustrated), as disclosed in, for example, U.S. Patent Application Publication No. 2003/0025890 and the like. Illumination system 10 illuminates a slit-shaped illumination area IAR, which is defined by the reticle blind (which is also referred to as a masking system), on reticle R with illumination light (exposure light) IL with substantially uniform illuminance. As illumination light IL, ArF excimer laser light (wavelength: 193 nm) is used as an example.

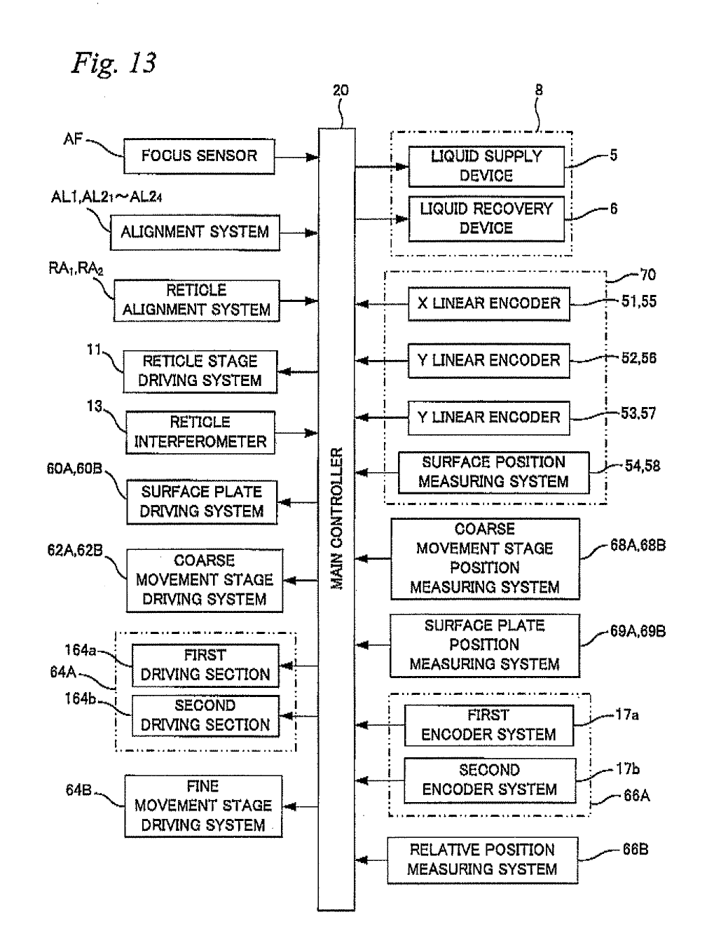

On reticle stage RST, reticle R having a pattern surface (the lower surface in FIG. 1) on which a circuit pattern and the like are formed is fixed by, for example, vacuum adsorption. Reticle stage RST can be driven with a predetermined stroke at a predetermined scanning speed in a scanning direction (which is the Y-axis direction being a lateral direction of the page surface of FIG. 1) and can also be finely driven in the X-axis direction, with a reticle stage driving system 11 (not illustrated in FIG. 1, refer to FIG. 13) including, for example, a linear motor or the like.

Positional information within the XY plane (including rotational information in the θz direction) of reticle stage RST is constantly detected at a resolution of, for example, around 0.25 nm with a reticle laser interferometer (hereinafter, referred to as a “reticle interferometer”) 13 via a movable mirror 15 fixed to reticle stage RST (actually, a Y movable mirror (or a retroreflector) that has a reflection surface orthogonal to the Y-axis direction and an X movable mirror that has a reflection surface orthogonal to the X-axis direction are arranged). The measurement values of reticle interferometer 13 are sent to a main controller 20 (not illustrated in FIG. 1, refer to FIG. 13). Incidentally, the positional information of reticle stage RST can be measured by an encoder system as is disclosed in, for example, U.S. Patent Application Publication 2007/0288121 and the like.

Above reticle stage RST, a pair of reticle alignment systems RA₁ and RA₂ by an image processing method, each of which has an imaging device such as a CCD and uses light with an exposure wavelength (illumination light IL in the present embodiment) as alignment illumination light, are placed (in FIG. 1, reticle alignment system RA₂ hides behind reticle alignment system RA₁ in the depth of the page surface), as disclosed in detail in, for example, U.S. Pat. No. 5,646,413 and the like. Main controller 20 (refer to FIG. 13) detects projected images of a pair of reticle alignment marks (drawing omitted) formed on reticle R and a pair of first fiducial marks on a measurement plate, which is described later, on fine movement stage WFS1 (or WFS2), that correspond to the reticle alignment marks via projection optical system PL in a state where the measurement plate is located directly under projection optical system PL, and the pair of reticle alignment systems RA₁ and RA₂ are used to detect a positional relation between the center of a projection area of a pattern of reticle R by projection optical system PL and a fiducial position on the measurement plate, i.e. the center of the pair of the first fiducial marks, according to such detection performed by main controller 20. Detection signals of reticle alignment detection systems RA₁ and RA₂ are supplied to main controller 20 (refer to FIG. 13) via a signal processing system (not shown) Incidentally, reticle alignment systems RA₁ and RA₂ do not have to be arranged. In such a case, it is preferable that a detection system that has a light-transmitting section (photodetection section) arranged at a fine movement stage, which is described later on, is installed so as to detect projected images of the reticle alignment marks, as disclosed in, for example, U.S. Patent Application Publication No. 2002/0041377 and the like.

Projection unit PU is placed below reticle stage RST in FIG. 1. Projection unit PU is supported, via a flange section FLG that is fixed to the outer periphery of projection unit PU, by a main frame (which is also referred to as a metrology frame) BD that is horizontally supported by a support member that is not illustrated. Main frame BD can be configured such that vibration from the outside is not transmitted to the main frame or the main frame does not transmit vibration to the outside, by arranging a vibration isolating device or the like at the support member. Projection unit PU includes a barrel 40 and projection optical system PL held within barrel 40. As projection optical system PL, for example, a dioptric system that is composed of a plurality of optical elements (lens elements) that are disposed along optical axis AX parallel to the Z-axis direction is used. Projection optical system PL is, for example, both-side telecentric and has a predetermined projection magnification (e.g. one-quarter, one-fifth, one-eighth times, or the like). Therefore, when illumination area IAR on reticle R is illuminated with illumination light IL from illumination system 10, illumination light IL passes through reticle R whose pattern surface is placed substantially coincident with a first plane (object plane) of projection optical system PL. Then, a reduced image of a circuit pattern (a reduced image of apart of a circuit pattern) of reticle R within illumination area IAR is formed in an area (hereinafter, also referred to as an exposure area) IA that is conjugate to illumination area IAR described above on wafer W which is placed on the second plane (image plane) side of projection optical system PL and whose surface is coated with a resist (sensitive agent), via projection optical system PL (projection unit PU). Then, by moving reticle R relative to illumination area IAR (illumination light IL) in the scanning direction (Y-axis direction) and also moving wafer W relative to exposure area IA (illumination light IL) in the scanning direction (Y-axis direction) by synchronous drive of reticle stage RST and wafer stage WST1 (or WST2), scanning exposure of one shot area (divided area) on wafer W is performed. Accordingly, a pattern of reticle R is transferred onto the shot area. More specifically, in the embodiment, a pattern of reticle R is generated on wafer W by illumination system 10 and projection optical system PL, and the pattern is formed on wafer W by exposure of a sensitive layer (resist layer) on wafer W with illumination light (exposure light) IL. In this case, projection unit PU is held by main frame BD, and in the embodiment, main frame BD is substantially horizontally supported by a plurality (e.g. three or four) of support members placed on an installation surface (such as a floor surface) each via a vibration isolating mechanism. Incidentally, the vibration isolating mechanism can be placed between each of the support members and main frame BD. Further, as disclosed in, for example, PCT International Publication No. 2006/038952, main frame BD (projection unit PU) can be supported in a suspended manner by a main frame member (not illustrated) placed above projection unit PU or a reticle base or the like.

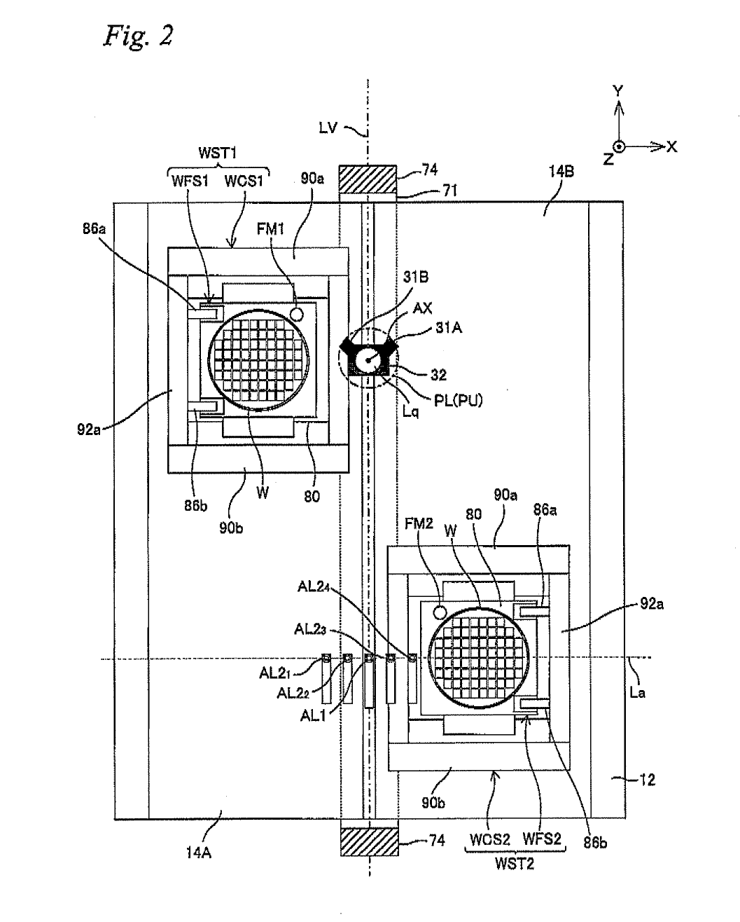

Local liquid immersion device 8 includes a liquid supply device 5, a liquid recovery device 6 (none of which are illustrated in FIG. 1, refer to FIG. 13), and a nozzle unit 32 and the like. As shown in FIG. 1, nozzle unit 32 is supported in a suspended manner by main frame BD that supports projection unit PU and the like, via a support member that is not illustrated, so as to enclose the periphery of the lower end of barrel 40 that holds an optical element closest to the image plane side (wafer W side) that configures projection optical system PL, which is a lens (hereinafter, also referred to as a “tip lens”) 191 in this case. Nozzle unit 32 is equipped with a supply opening and a recovery opening of a liquid Lq, a lower surface to which wafer W is placed so as to be opposed and at which the recovery opening is arranged, and a supply flow channel and a recovery flow channel that are respectively connected to a liquid supply pipe 31A and a liquid recovery pipe 31B (none of which are illustrated in FIG. 1, refer to FIG. 2). One end of a supply pipe (not illustrated) is connected to liquid supply pipe 31A, while the other end of the supply pipe is connected to liquid supply device 5, and one end of a recovery pipe (not illustrated) is connected to liquid recovery pipe 31B, while the other end of the recovery pipe is connected to liquid recovery device 6.

In the present embodiment, main controller 20 controls liquid supply device 5 (refer to FIG. 13) to supply the liquid to the space between tip lens 191 and wafer W and also controls liquid recovery device 6 (refer to FIG. 13) to recover the liquid from the space between tip lens 191 and wafer W. On this operation, main controller 20 controls the quantity of the supplied liquid and the quantity of the recovered liquid in order to hold a constant quantity of liquid Lq (refer to FIG. 1) while constantly replacing the liquid in the space between tip lens 191 and wafer W. In the embodiment, as the liquid described above, pure water (with a refractive index n 1.44) that transmits the ArF excimer laser light (the light with a wavelength of 193 nm) is to be used.

Measurement station 300 is equipped with an alignment device 99 arranged at main frame BD. Alignment device 99 includes five alignment systems AL1 and AL2₁ to AL2₄ shown in FIG. 2, as disclosed in, for example, U.S. Patent Application Publication No. 2008/0088843 and the like. To be more Specific, as shown in FIG. 2, a primary alignment system AL1 is placed in a state where its detection center is located at a position a predetermined distance apart on the −Y side from optical axis AX, on a straight line (hereinafter, referred to as a reference axis) LV that passes through the center of projection unit PU (which is optical axis AX of projection optical system PL, and in the present embodiment, which also coincides with the center of exposure area IA described previously) and is parallel to the Y-axis. On one side and the other side in the X-axis direction with primary alignment system AL1 in between, secondary alignment systems AL2₁ and AL2₂, and AL2₃ and AL2₄, whose detection centers are substantially symmetrically placed with respect to reference axis LV, are arranged respectively. More specifically, the detection centers of the five alignment systems AL1 and AL2₁ to AL2₄ are placed along a straight line (hereinafter, referred to as a reference axis) LA that vertically intersects reference axis LV at the detection center of primary alignment system AL1 and is parallel to the X-axis. Incidentally, in FIG. 1, the five alignment systems AL1 and AL2₁ to AL2₄, including a holding device (slider) that holds these alignment systems are shown as alignment device 99. As disclosed in, for example, U.S. Patent Application Publication No. 2009/0233234 and the like, secondary alignment systems AL2₁ to AL2₄ are fixed to the lower surface of main frame BD via the movable slider (refer to FIG. 1), and the relative positions of the detection areas of the secondary alignment systems are adjustable at least in the X-axis direction with a drive mechanism that is not illustrated.

In the present embodiment, as each of alignment systems AL1 and AL2₁ to AL2₄, for example, an FIA (Field Image Alignment) system by an image processing method is used. The configurations of alignment systems AL1 and AL2₁ to AL2₄ are disclosed in detail in, for example, PCT International Publication No. 2008/056735 and the like. The imaging signal from each of alignment systems AL1 and AL2₁ to AL2₄ is supplied to main controller 20 (refer to FIG. 13) via a signal processing system that is not illustrated.

Incidentally, although it is not illustrated, exposure apparatus 100 has a first loading position where load of the wafer to wafer stage WST1 and unload of the wafer from wafer stage WST1 is performed, and a second loading position where load of the wafer to wafer stage WST2 and unload of the wafer from wafer stage WST1 is performed. In the case of the present embodiment, the first loading position is arranged on the surface plate 14A side and the second loading position is arranged on the surface plate 143 side.

As shown in FIG. 1, stage device 50 is equipped with base board 12, a pair of surface plates 14A and 143 placed above base board 12 (in FIG. 1, surface plate 143 is hidden behind surface plate 14A in the depth of the page surface), two wafer stages WST1 and WST2 that move on a guide surface parallel to the XY plane formed on the upper surface of the pair of surface plates 14A and 14B, and a measuring system that measures positional information of wafer stages WST1 and WST2.

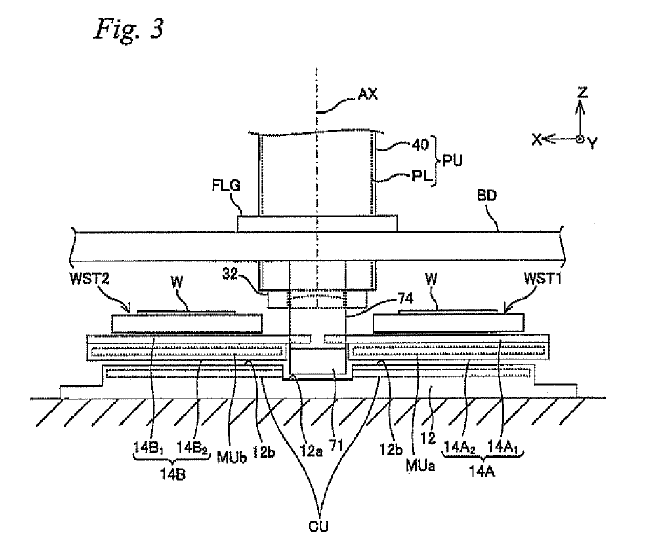

Base board 12 is made up of a member having a tabular outer shape, and as shown in FIG. 1, is substantially horizontally (parallel to the XY plane) supported via a vibration isolating mechanism (drawing omitted) on a floor surface 102. In the center portion in the X-axis direction of the upper surface of base board 12, a recessed section 12a (recessed groove) extending in a direction parallel to the Y-axis is formed, as shown in FIG. 3. On the upper surface side of base board 12 (excluding a portion where recessed section 12a is formed, in this case), a coil unit CU is housed that includes a plurality of coils placed in the shape of a matrix with the XY two-dimensional directions serving as a row direction and a column direction. Incidentally, the vibration isolating mechanism does not necessarily have to be arranged.

As shown in FIG. 2, surface plates 14A and 14B are each made up of a rectangular plate-shaped member whose longitudinal direction is in the Y-axis direction in a planar view (when viewed from above) and are respectively placed on the −X side and the +X side of reference axis LV. Surface plate 14A and surface plate 14B are placed with a very narrow gap therebetween in the X-axis direction, symmetric with respect to reference axis LV. By finishing the upper surface (the +Z side surface) of each of surface plates 14A and 14B such that the upper surface has a very high flatness degree, it is possible to make the upper surfaces function as the guide surface with respect to the Z-axis direction used when each of wafer stages WST1 and WST2 moves following the XY plane. Alternatively, a configuration can be employed in which a force in the Z-axis direction is made to act on wafer stages WST1 and WST2 by planar motors, which are described later on, to magnetically levitate wafer stages WST1 and WST2 above surface plates 14A and 14B. In the case of the present embodiment, the configuration that uses the planar motors is employed and static gas bearings are not used, and therefore, the flatness degree of the upper surfaces of surface plates 14A and 14B does not have to be so high as in the above description.

As shown in FIG. 3, surface plates 14A and 14B are supported on upper surfaces 12b of both side portions of recessed section 12a of base board 12 via air bearings (or rolling bearings) that are not illustrated.

Surface plates 14A and 14B respectively have first sections 14A₁ and 14B₁ each having a relatively thin plate shape on the upper surface of which the guide surface is formed, and second sections 14A₂ and 14B₂ each having a relatively thick plate shape and being short in the X-axis direction that are integrally fixed to the lower surfaces of first sections 14A₁, and 14B₁, respectively. The end on the +X side of first section 14A₁ of surface plate 14A slightly overhangs, to the +X side, the end surface on the +X side of second section 14A₂, and the end on the −X side of first section 14B₁ of surface plate 14B slightly overhangs, to the −X side, the end surface on the −X side of second section 14B₂. However, the configuration is not limited to the above-described one, and a configuration can be employed in which the overhangs are not arranged.

Inside each of first sections 14A₁ and 14B₁, a coil unit (drawing omitted) is housed that includes a plurality of coils placed in a matrix shape with the XY two-dimensional directions serving as a row direction and a column direction. The magnitude and direction of the electric current supplied to each of the plurality of coils that configure each of the coil units are controlled by main controller 20 (refer to FIG. 13).

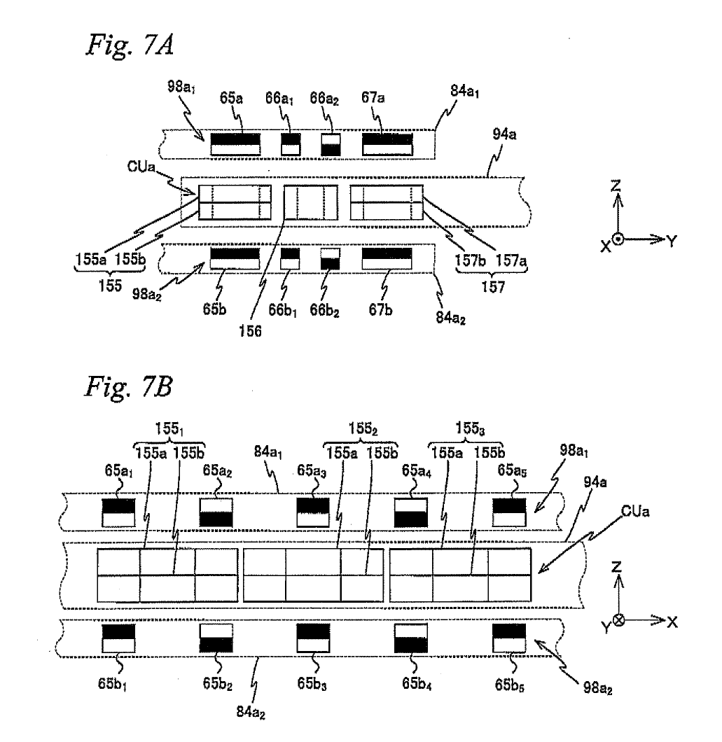

Inside (on the bottom portion of) second section 14A₂ of surface plate 14A, a magnetic unit MUa, which is made up of a plurality of permanent magnets (and yokes not shown) placed in the shape of a matrix with the XY two-dimensional directions serving as a row direction and a column direction, is housed so as to correspond to coil unit CU housed on the upper surface side of base board 12. Magnetic unit MUa configures, together with coil unit CU of base board 12, a surface plate driving system 60A (refer to FIG. 7) that is made up of a planar motor by the electromagnetic force (Lorentz force) drive method that is disclosed in, for example, U.S. Patent Application Publication No. 2003/0085676 and the like. Surface plate driving system 60A generates a drive force that drives surface plate 14A in directions of three degrees of freedom (X, Y, θz) within the XY plane.

Similarly, inside on the bottom portion of) second section 14B₂ of surface plate 14B, a magnetic unit MUb made up of a plurality of permanent magnets (and yokes not shown) is housed that configures, together with coil unit CU of base board 12, a surface plate driving system 60B (refer to FIG. 13) made up of a planar motor that drives surface plate 143 in the directions of three degrees of freedom within the XY plane. Incidentally, the placement of the coil unit and the magnetic unit of the planar motor that configures each of surface plate driving systems 60A and 60B can be reverse (a moving coil type that has the magnetic unit on the base board side and the coil unit on the surface plate side) to the above-described case (a moving magnet type).

Positional information of surface plates 14A and 14B in the directions of three degrees of freedom is obtained (measured) independently from each other by a first surface plate position measuring system 69A and a second surface plate position measuring system 69B (refer to FIG. 13), respectively, which each include, for example, an encoder system. The output of each of first surface plate position measuring system 69A and second surface plate position measuring system 69B is supplied to main controller 20 (refer to FIG. 13), and main controller 20 controls the magnitude and direction of the electric current supplied to the respective coils that configure the coil units of surface plate driving systems 60A and 60B, based on the outputs of surface plate position measuring systems 69A and 69B, thereby controlling the respective positions of surface plates 14A and 14B in the directions of three degrees of freedom within the XY plane, as needed. Main controller 20 drives surface plates 14A and 14B via surface plate driving systems 60A and 60B based on the outputs of surface plate position measuring systems 69A and 69B to return surface plates 14A and 14B to the reference position of the surface plates such that the movement distance of surface plates 14A and 14B from the reference position falls within a predetermined range, when surface plates 14A and 14B function as the countermasses to be described later on. More specifically, surface plate driving systems 60A and 60B are used as trim motors.

While the configurations of first surface plate position measuring system 69A and second surface plate position measuring system 69B are not especially limited, an encoder system can be used in which, for example, encoder head sections, which obtain (measure) positional information of the respective surface plates 14A and 14B in the directions of three degrees of freedom within the XY plane by irradiating measurement beams on scales (e.g. two-dimensional gratings) placed on the lower surfaces of second sections 14A₂ and 14B₂ respectively and receiving diffraction light (reflected light) generated by the two-dimensional grating, are placed at base board 12 (or the encoder head sections are placed at second sections 14A₂ and 14B₂ and scales are placed at base board 12, respectively). Incidentally, it is also possible to obtain (measure) the positional information of surface plates 14A and 14B by, for example, an optical interferometer system or a measuring system that is a combination of an optical interferometer system and an encoder system.

One of the wafer stages, wafer stage WST1 is equipped with a fine movement stage WFS1 that holds wafer W and a coarse movement stage WCS1 having a rectangular frame shape that encloses the periphery of fine movement stage WFS1, as shown in FIG. 2. The other of the wafer stages, wafer stage WST2 is equipped with a fine movement stage WFS2 that holds wafer W and a coarse movement stage WCS2 having a rectangular frame shape that encloses the periphery of fine movement stage WFS2, as shown in FIG. 2. As is obvious from FIG. 2, wafer stage WST2 has completely the same configuration including the driving system, the position measuring system and the like, as wafer stage WST1 except that wafer stage WST2 is placed in a state laterally reversed with respect to wafer stage WST1. Consequently, in the description below, wafer stage WST1 is representatively focused on and described, and wafer stage WST2 is described only in the case where such description is especially needed.

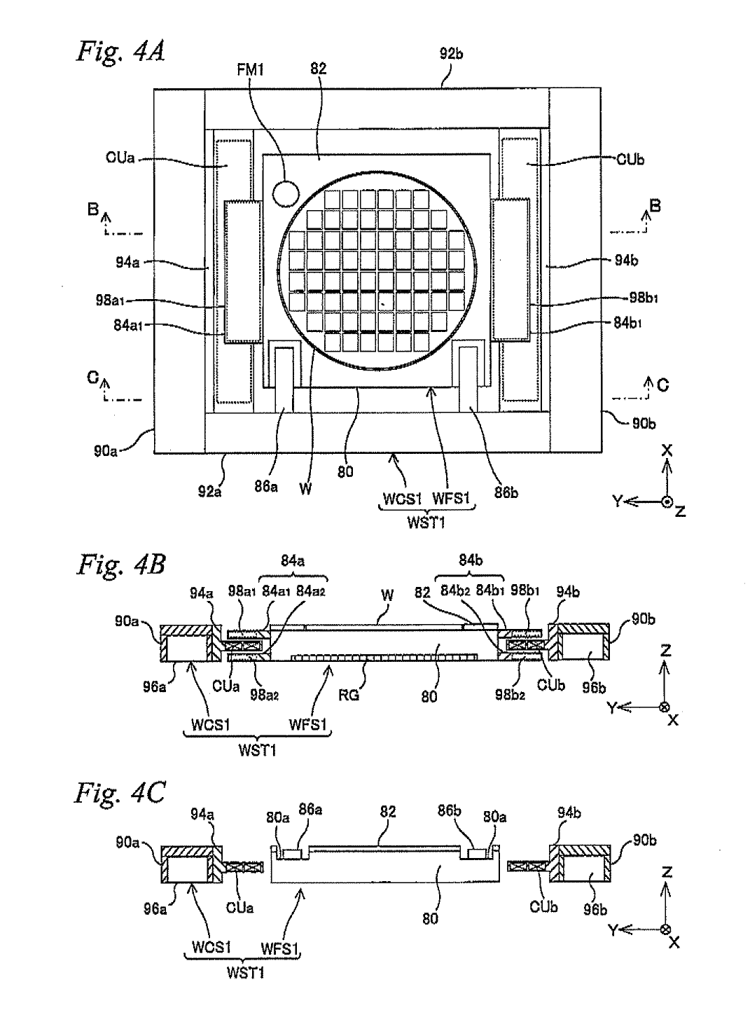

As shown in FIG. 4A, coarse movement stage WCS1 has a pair of coarse movement slider sections 90a and 90b which are placed parallel to each other, spaced apart in the Y-axis direction, and each of which is made up of a rectangular parallelepiped member whose longitudinal direction is in the X-axis direction, and a pair of coupling members 92a and 92b each of which is made up of a rectangular parallelepiped member whose longitudinal direction is in the Y-axis direction, and which couple the pair of coarse movement slider sections 90a and 90b with one ends and the other ends thereof in the Y-axis direction. More specifically, coarse movement stage WCS1 is formed into a rectangular frame shape with a rectangular opening section, in its center portion, that penetrates in the Z-axis direction.

Inside (on the bottom portions of) coarse movement slider sections 90a and 90b, as shown in FIGS. 4B and 4C, magnetic units 96a and 96b are housed respectively. Magnetic units 96a and 96b correspond to the coil units housed inside first sections 14A₁ and 14B₁ of surface plates 14A and 14B, respectively, and are each made of up a plurality of magnets placed in the shape of a matrix with the XY two-dimensional directions serving as a row direction and a column direction. Magnetic units 96a and 96b configure, together with the coil units of surface plates 14A and 14B, a coarse movement stage driving system 62A (refer to FIG. 13) that is made up of a planar motor by an electromagnetic force (Lorentz force) drive method that is capable of generating drive forces in the X-axis direction, the Y-axis direction, the Z-axis direction, the ex direction, the θy direction, and the θz direction (hereinafter described as directions of six degrees of freedom, or directions (X, Y, Z, θx, θy, and θz) of six degrees of freedom) to coarse movement stage WCS1, which is disclosed in, for example, U.S. Patent Application Publication No. 2003/0085676 and the like. Further, similar thereto, magnetic units, which coarse movement stage WCS2 (refer to FIG. 2) of wafer stage WST2 has, and the coil units of surface plates 14A and 14B configure a coarse movement stage driving system 62B (refer to FIG. 13) made up of a planar motor. In this case, since a force in the Z-axis direction acts on coarse movement stage WCS1 (or WCS2), the coarse movement stage is magnetically levitated above surface plates 14A and 14B. Therefore, it is not necessary to use static gas bearings for which relatively high machining accuracy is required, and thus it becomes unnecessary to increase the flatness degree of the upper surfaces of surface plates 14A and 14B.

Incidentally, while coarse movement stages WCS1 and WCS2 of the present embodiment have the configuration in which only coarse movement slider sections 90a and 90b have the magnetic units of the planar motors, the present embodiment is not limited to this, and the magnetic unit can be placed also at coupling members 92a and 92b. Further, the actuators to drive coarse movement stages WCS1 and WCS2 are not limited to the planar motors by the electromagnetic force (Lorentz force) drive method, but for example, planar motors by a variable magnetoresistance drive method or the like can be used. Further, the drive directions of coarse movement stages WCS1 and WCS2 are not limited to the directions of six degrees of freedom, but can be, for example, only directions of three degrees of freedom (X, Y, θz) within the XY plane. In this case, coarse movement stages WCS1 and WCS2 should be levitated above surface plates 14A and 14B, for example, using static gas bearings (e.g. air bearings). Further, in the present embodiment, while the planar motor of a moving magnet type is used as each of coarse movement stage driving systems 62A and 62B, besides this, a planar motor of a moving coil type in which the magnetic unit is placed at the surface plate and the coil unit is placed at the coarse movement stage can also be used.

On the side surface on the −Y side of coarse movement slider 90a and on the side surface on the +Y side of coarse movement slider 90b, stator sections 94a and 94b that configure a part of fine movement stage driving system 64 (refer to FIG. 13) which will be described later that finely drives fine movement stage WFS1 are respectively fixed. As shown in FIG. 4B, stator section 94a is made up of a member having a T-like sectional shape arranged extending in the x-axis direction and its lower surface is placed flush with the lower surface of coarse movement slider 90a. Stator section 94b is configured and placed similar to stator section 94a, although guide member 94b is bilaterally symmetric to stator section 94a.

Inside (on the bottom section of) stator sections 94a and 94b, a pair of coil units CUa and Cub, each of which includes a plurality of coils placed in the shape of a matrix with the XY two-dimensional directions serving as a row direction and a column direction, are housed, respectively (refer to FIG. 4A). The magnitude and direction of the electric current supplied to each of the coils that configure coil units CUa and CUb are controlled by main controller 20 (refer to FIG. 13).

Inside coupling members 92a and/or 92b, various types of optical members (e.g. an aerial image measuring instrument, an uneven illuminance measuring instrument, an illuminance monitor, a wavefront aberration measuring instrument, and the like) can be housed.

In this case, when wafer stage WST1 is driven with acceleration/deceleration in the Y-axis direction on surface plate 14A, by the planar motor that configures coarse movement stage driving system 62A (e.g. when wafer stage WST1 moves between exposure station 200 and measurement station 300), surface plate 14A moves in a direction opposite to wafer stage WST1 according to the so-called law of action and reaction (the law of conservation of momentum) due to the action of a reaction force of the drive of wafer stage WST1. Further, it is also possible to make a state where the law of action and reaction described above does not hold, by generating a drive force in the Y-axis direction with surface plate driving system 60A.

Further, when wafer stage WST2 is driven in the Y-axis direction on surface plate 14B, surface plate 14B is also driven in a direction opposite to wafer stage WST2 according to the so-called law of action and reaction (the law of conservation of momentum) due to the action of a reaction force of a drive force of wafer stage WST2. More specifically, surface plates 14A and 14B function as the countermasses and the momentum of a system composed of wafer stages WST1 and WST2 and surface plates 14A and 14B as a whole is conserved and movement of the center of gravity does not occur. Consequently, any inconveniences do not arise such as the uneven loading acting on surface plates 14A and 14B owing to the movement of wafer stages WST1 and WST2 in the Y-axis direction. Incidentally, regarding wafer stage WST2 as well, it is possible to make a state where the law of action and reaction described above does not hold, by generating a drive force in the Y-axis direction with surface plate driving system 60B.

Further, on movement in the X-axis direction of wafer stages WST1 and WST2, surface plates 14A and 14B function as the countermasses owing to the action of a reaction force of the drive force.

As shown in FIGS. 4A and 4B, fine movement stage WFS1 is equipped with a main section 80 made up of a member having a rectangular shape in a planar view, a mover section 84a fixed to the side surface on the +Y side of main section 80, and a mover section 84b fixed to the side surface on the −Y side of main section 80.

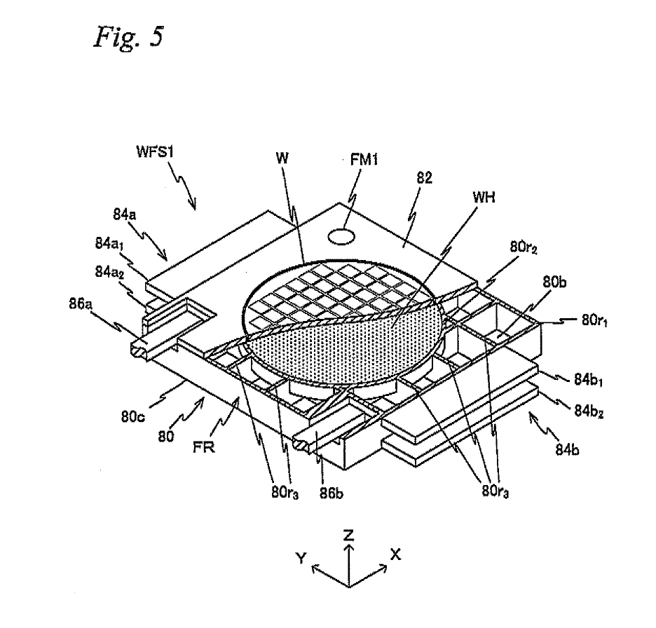

As shown in FIG. 5 in a partially broken view of fine movement stage WFS1 (WFS2), main section 80 has to (a plate) 82, a framing member 80c, and a bottom 80b. Plate 82 has a rectangular shape in a planar view (when viewed from above). However, in the center, a circular opening which is slightly larger than wafer W is formed, and on the −X end, two rectangular notches into which the tip of tubes 86a and 86b are inserted are formed. Framing member 80c has an outer wall 80r₁ which has the same shape as the outer shape (contour) of plate 82, an inner wall 80r₂ which divides a circular hole section, and a plurality of ribs 80r₃ which connects outer wall 80r₁ and inner wall 80r₂. Incidentally, the plurality of ribs 80r₃ have recess sections corresponding to the hole section, and inner wall 80r₂ is fixed by the plurality of ribs 80r₃, in a state where inner wall 80r₂ is fitted into the recess sections. Bottom section 80b has the same rectangular shape as plate 82.

Plate 82 is fixed and integrated to the upper surface of framing member 80c, so that its entire surface (or a part of the surface) becomes flush with the surface of wafer W held by wafer holder WH, which will be described later on. On this integration, outer wall 80r₁ and inner wall 80r₂ support the outer edge and the inner edge of plate 82, respectively. Further, the surfaces of plate 82 and wafer W are located substantially flush with the surface of coupling member 92b described previously.

Bottom section 80b is fixed to a bottom surface of framing member 81c. In this case, by plate 82, framing member 80c, bottom section 80b, and inner wall 80r₂, a space is formed sectioned by the plurality of ribs 80r₃, inside main section 80. Incidentally, in the embodiment, fine movement stage WFS1 (WFS2) is supported by coarse movement stage WCS1 (WCS2) in a state where the lower surface of bottom section 80b is positioned on the same plane as the lower surface of coarse movement stage WCS1.

Main section 80 is configured of a material that is lighter, stronger, and has a low thermal expansion, such as for example, ceramics. In the case of using ceramics, main section 80 can be made integrally, except for plate 82. Now, to strengthen (to provide high rigidity to) main section 80, rib 80r₃ can be further increased, or the plurality of ribs can be combined into an appropriate shape, such as in a radiating shape and the like.

In the circular recess section divided by inner wall 80r₂, a wafer holder that holds wafer W by vacuum adsorption or the like is placed. Incidentally, wafer holder WH can be fixed to main section 80 so as to be detachable via, for example, a holding mechanism such as an electrostatic chuck mechanism or a clamp mechanism. Further, wafer holder WH can be fixed to main section 80 by an adhesive agent or the like.

In the embodiment, in fine movement stage WFS1 (or WFS2) because a hollow section is formed inside main section 80 to decrease its weight, position controllability of fine movement stage WFS1 (or WFS2) can be improved. In this case, a heat insulating material can be placed in the hollow section formed in main section 80 of fine movement stage WFS1 (WFS2) This makes it possible to prevent any adverse effect that the heat generated in the fine movement stage drive system including the magnetic unit which will be described later in the pair of mover sections 84a and 84b has on grating RG.

The liquid-repellent treatment against liquid Lq is applied to the surface of plate 82 (the liquid-repellent surface is formed). In the embodiment, the surface of plate 82 includes a base material made up of metal, ceramics, glass or the like, and a film of liquid-repellent material formed on the surface of the base material. The liquid-repellent material includes, for example, PFA (Tetra fluoro ethylene-perfluoro alkylvinyl ether copolymer), PTFE (Poly tetra fluoro ethylene), Teflon (registered trademark) or the like. Incidentally, the material that forms the film can be an acrylic-type resin or a silicon-series resin. Further, the entire plate 82 can be formed with at least one of the PFA, PTFE, Teflon (registered trademark), acrylic-type resin and silicon-series resin. In the present embodiment, the contact angle of the upper surface of plate 82 with respect to liquid Lq is, for example, more than or equal to 90 degrees. On the surface of coupling member 92b described previously as well, the similar liquid-repellent treatment is applied.

Further, in the vicinity of a corner on the +X side located on the +Y side of plate 82, a circular opening is formed, and a measurement plate FM1 is placed in the opening without any gap therebetween in a state substantially flush with the surface of wafer W. On the upper surface of measurement plate FM1, the pair of first fiducial marks to be respectively detected by the pair of reticle alignment systems RA₁ and RA₂ (refer to FIGS. 1 and 13) described earlier and a second fiducial mark to be detected by primary alignment system AL1 (none of the marks are shown) are formed. In fine movement stage WFS2 of wafer stage WST2, as shown in FIG. 2, in the vicinity of a corner on the −X side located on the +Y side of plate 82, a measurement plate FM2 that is similar to measurement plate FM1 is fixed in a state substantially flush with the surface of wafer W. Incidentally, instead of attaching plate 82 to fine movement stage WFS1 (main section 80), it is also possible, for example, that the wafer holder is formed integrally with fine movement stage WFS1 and the liquid-repellent treatment is applied to the peripheral area, which encloses the wafer holder (the same area as plate 82 (which may include the surface of the measurement plate)), of the upper surface of fine movement stage WFS1 and the liquid repellent surface is formed.

In the center of the lower surface of main section 80 (bottom section 80b), as shown in FIG. 4B, a plate having a predetermined thin plate shape, which is large to the extent of covering wafer holder WH and measurement plate FM1 (or measurement plate FM2 in the case of fine movement stage WFS2), is placed in a state where its lower surface is located substantially flush with the other section (the peripheral section) (the lower surface of the plate does not protrude below the peripheral section). On one surface (the upper surface (or the lower surface)) of the plate, two-dimensional grating RG (hereinafter, simply referred to as grating RG) is formed. Grating RG includes a reflective diffraction grating (X diffraction grating) whose periodic direction is in the X-axis direction and a reflective diffraction grating (Y diffraction grating) whose periodic direction is in the Y-axis direction. The plate is formed by, for example, glass, and grating RG is created by graving the graduations of the diffraction gratings at a pitch, for example, between 138 nm to 4 m, e.g. at a pitch of 1 m. Incidentally, grating RG can also cover the entire lower surface of main section 80 (bottom section 80b). Further, the type of the diffraction grating used for grating RG is not limited to the one on which grooves or the like are formed, but for example, a diffraction grating that is created by exposing interference fringes on a photosensitive resin can also be employed. Incidentally, the configuration of the plate having a thin plate shape is not necessarily limited to the above-described one.

As shown in FIGS. 4A and 4B, mover section 84a includes two plate-like members 84a₁ and 84a₂ having a rectangular shape in a planar view whose size (length) in the X-axis direction and size (width) in the Y-axis direction are both shorter than stator section 84a. Plate-like members 84a₁ and 84a₂ are fixed to a side surface of main section 80 on the +Y side, placed apart in the Z-axis direction (vertically) by a predetermined distance and in parallel to the XY plane. Between the two plate-like members 84a₁ and 84a₂, an end on the −Y side of stator section 94a is inserted in a non-contact manner. Inside plate-like member 84a₁, a magnet unit 98a₁ which will be described later is housed, and inside plate-like member 84a₂, a magnet unit 98a₂ which will be described later is housed.

Mover section 84b includes two plate-like members 84b₁ and 84b₂, and is configured in a similar manner as mover section 84a, although being symmetrical. Between the two plate-like members 84b₁ and 84b₂, an end on the +Y side of stator section 94b is inserted in a non-contact manner. Inside each of plate-like members 84b₁ and 84b₂, magnet units 98b₁ and 98b₂ that are configured similar to magnet units 98a₁ and 98a₂ are housed.

Next, a configuration of fine movement stage drive system 64A (refer to FIG. 13) to drive fine movement stage WFS1 with respect to coarse movement stage WCS1 will be described. Fine movement stage drive system 64A includes the pair of magnet units 98a₁ and 98a₂ that mover section 84a previously described has, coil unit CUa that stator section 94a has, the pair of magnet units 98b₁ and 98b₂ that mover section 84b previously described has, and coil unit Cub that stator section 94b has.

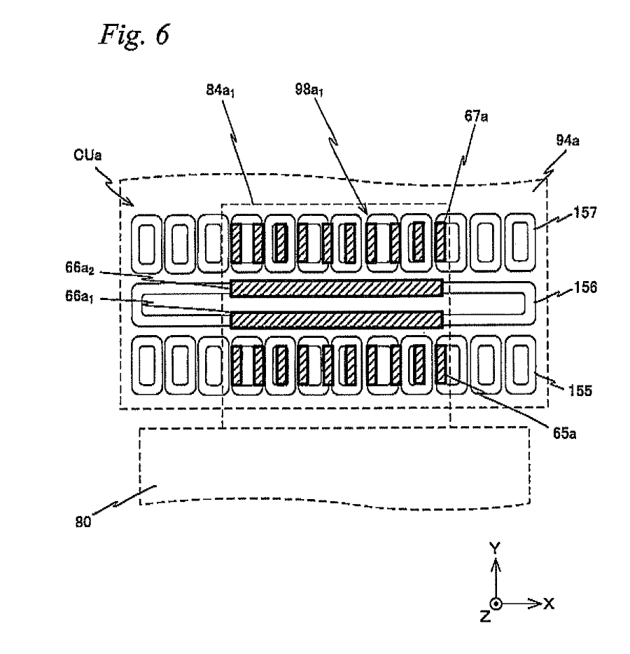

This will be explained further in detail. As it can be seen from FIGS. 6, 7A, and 7B, inside stator section 94a, two lines of coil rows are placed a predetermined distance apart in the Y-axis direction, which are a plurality of (in this case, twelve) XZ coils (hereinafter appropriately referred to as “coils”) 155 and 157 that have a rectangular shape in a planar view and are placed equally apart in the X-axis direction. XZ coil 155 has an upper part winding 155a and a lower part winding 155b in a rectangular shape in a planar view that are disposed such that they overlap in the vertical direction (the Z-axis direction). Further, between the two lines of coil rows described above inside stator section 94a, a Y coil (hereinafter shortly referred to as a “coil” as appropriate) 156 is placed, which is narrow and has a rectangular shape in a planar view and whose longitudinal direction is in the X-axis direction. In this case, the two lines of coil rows and Y coil 156 are placed equally spaced in the Y-axis direction. Coil unit CUa is configured including the two lines of coil rows and Y coil 156.

Incidentally, in the description below, while one of the stator sections 94a and mover sections 84a, which have coil unit CUa and magnet units 98a₁ and 98a₂, respectively, will be described using FIGS. 6 to 8C, the other stator section 94b and mover section 84b will be structured similar to these sections and will function in a similar manner.

Inside plate-like member 84a₁ on the +Z side configuring apart of mover section 84a, as it can be seen when referring to FIGS. 6, 7A, and 7B, two lines of magnet rows are placed a predetermined distance apart in the Y-axis direction, which are a plurality of (in this case, ten) permanent magnets 65a and 67a that are placed at an equal distance in the X-axis direction having a rectangular shape in a planar view and whose longitudinal direction is in the Y-axis direction. The two lines of magnet rows are placed facing coils 155 and 157, respectively. Further, between the two lines of magnet rows described above inside plate-like member 84a₁, a pair (two) of permanent magnets 66a₁ and 66a₂ whose longitudinal direction is in the X-axis direction is placed set apart in the Y-axis direction, facing coil 156.

The plurality of permanent magnets 65a is placed in an arrangement where the magnets have a polarity which is alternately a reverse polarity to each other, as shown in FIG. 7B. The magnet row consisting of the plurality of permanent magnets 67a is structured similar to the magnet row consisting of the plurality of permanent magnets 65a. Further, as shown in FIG. 7A, permanent magnets 66a₁ and 66a₂ are placed so that the polarity to each other is a reverse polarity. Magnet unit 98a₁ is configured by the plurality of permanent magnets 65a and 67a, and 66a₁ and 66a₂.

As shown in FIG. 7A, also inside plate-like member 84a₂ on the −Z side, permanent magnets 65b, 66b₁, 66b₂, and 67b are placed in a placement similar to plate-like member 84a₁ described above. Magnet unit 98a₂ is configured by these permanent magnets 65b, 66b₁, 66b₂, and 67b. Incidentally, in FIG. 6, permanent magnets 65b, 66b₁, 66b₂, and 67b are placed in the depth of the page surface, with magnets 65a, 66a₁, 66a₂, and 67a placed on top.

Now, as shown in FIG. 7B, positional relation (each distance) in the X-axis direction between the plurality of permanent magnets 65 and the plurality of XZ coils 155 is set so that when in the plurality of permanent magnets (in FIG. 7B, permanent magnets 65a₁ to 65a₅ which are sequentially arranged along the X-axis direction) placed adjacently in the X-axis direction, two adjacent permanent magnets 65a₁ and 65a₂ each face the winding section of XZ coil 155₁, then permanent magnet 65a₃ adjacent to these permanent magnets does not face the winding section of XZ coil 155₂ adjacent to XZ coil 155₁ described above (so that permanent magnet 65a₃ faces the hollow center in the center of the coil, or faces a core, such as an iron core, to which the coil is wound). In this case, as shown in FIG. 7B, permanent magnets 65a₄ and 65a₅ respectively face the winding section of XZ coil 155₃, which is adjacent to XZ coil 155₂. The distance between permanent magnets 65b, 67a, and 67b in the X-axis direction is also similar (refer to FIG. 7B).

Accordingly, in fine movement stage driving system 64A, as an example, when a clockwise electric current when viewed from the +Z direction is supplied to the upper part winding and the lower part winding of coils 155₁ and 155₃, respectively, as shown in FIG. 5A in a state shown in FIG. 7B, a force (Lorentz force) in the −X direction acts on coils 155₁ and 155₃, and as a reaction force, a force in the +X direction acts on permanent magnets 65a and 65b. By these action of forces, fine movement stage WFS1 moves in the +X direction with respect to coarse movement stage WCS1. When a current of a reverse direction is supplied to each of the coils 155₁ and 155₃ conversely to the case described above, fine movement stage WFS1 moves in the −X direction with respect to coarse movement stage WCS1.

By supplying an electric current to coil 157, electromagnetic interaction is performed between permanent magnet 67 (67a, 67b) and fine movement stage WFS1 can be driven in the X-axis direction. Main controller 20 controls a position of fine movement stage WFS1 in the X-axis direction by controlling the current supplied to each coil.

Further, in fine movement stage driving system 64A, as an example, when a counterclockwise electric current when viewed from the +Z direction is supplied to the upper part winding of coil 155₂ and a clockwise electric current when viewed from the +Z direction is supplied to the lower part winding as shown in FIG. 83 in a state shown in FIG. 7B, an attraction force is generated between coil 155₂ and permanent magnet 65a₃ whereas a repulsive force (repulsion) is generated between coil 155₂ and permanent magnet 65b₃, respectively, and by these attraction force and repulsive force, fine movement stage WFS1 is moved downward (−Z direction) with respect to coarse movement stage WSC1, or more particularly, moved in a descending direction. When a current in a direction opposite to the case described above is supplied to the upper part winding and the lower part winding of coil 155₂, respectively, fine movement stage WFS1 moves upward (+Z direction) with respect to coarse movement stage WCS1, or more particularly, moves in an upward direction. Main controller 20 controls a position of fine movement stage WFS1 in the Z direction which is in a levitated state by controlling the current supplied to each coil.

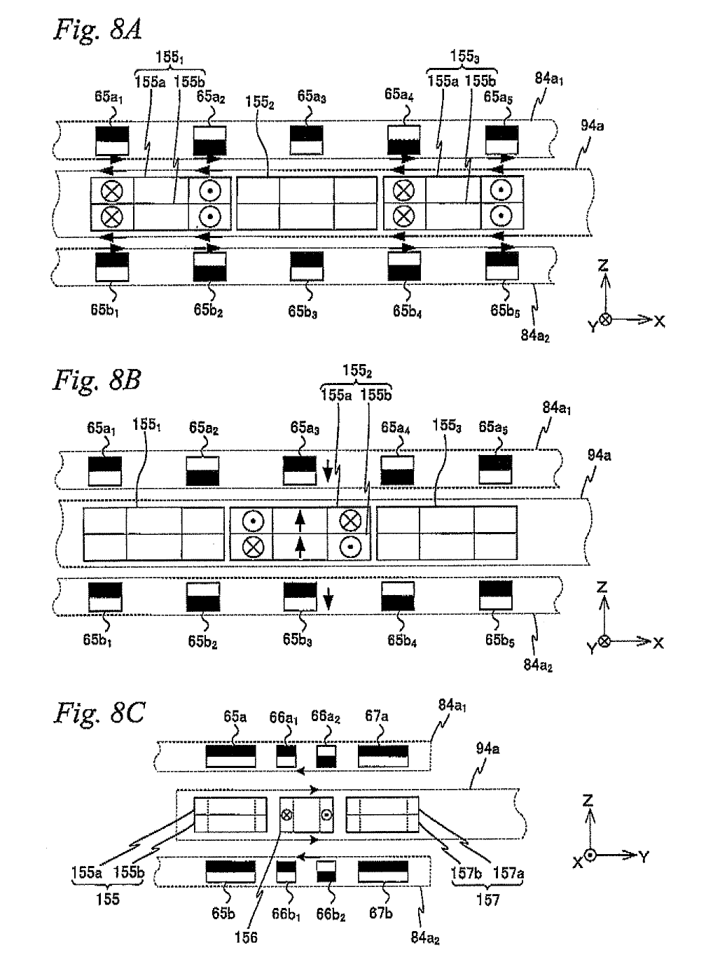

Further, in a state shown in FIG. 7A, when a clockwise electric current when viewed from the +Z direction is supplied to coil 156, a force in the +Y direction acts on coil 155 as shown in FIG. 8C, and as its reaction, a force in the −Y direction acts on permanent magnets 66a₁ and 66a₂, and 66b₁ and 66b₂, respectively, and fine movement stage WFS1 is moved in the −Y direction with respect to coarse movement stage WSC1. Further, when a current in a direction opposite to the case described above is supplied to coil 156, a force in the +Y direction acts on permanent magnets 66a₁ and 66a₂, and 66b₁ and 66b₂, and fine movement stage WFS1 is moved in the +Y direction with respect to coarse movement stage WCS1. Main controller 20 controls a position of fine movement stage WFS1 in the Y-axis direction by controlling the current supplied to each coil.

As is obvious from the description above, in the embodiment, main controller 20 drives fine movement stage WFS1 in the X-axis direction by supplying an electric current alternately to the plurality of XZ coils 155 and 157 that are arranged in the X-axis direction. Further, along with this, by supplying electric current to coils of XZ coils 155 and 157 that are not used to drive fine movement stage WFS1 in the X-axis direction, main controller 20 generates a drive force in the Z-axis direction separately from the drive force in the X-axis direction and makes fine movement stage WFS1 levitate from coarse movement stage WCS1. And, main controller 20 drives fine movement stage WFS1 in the X-axis direction while maintaining the levitated state of fine movement stage WFS1 with respect to coarse movement stage WCS1, namely a noncontact state, by sequentially switching the coil subject to current supply according to the position of fine movement stage WFS1 in the X-axis direction. Further, main controller 20 can drive fine movement stage WFS1 in the X-axis direction in a state where fine movement stage WFS1 is levitated from coarse movement stage WCS1, as well as independently drive the fine movement stage in the Y-axis direction.

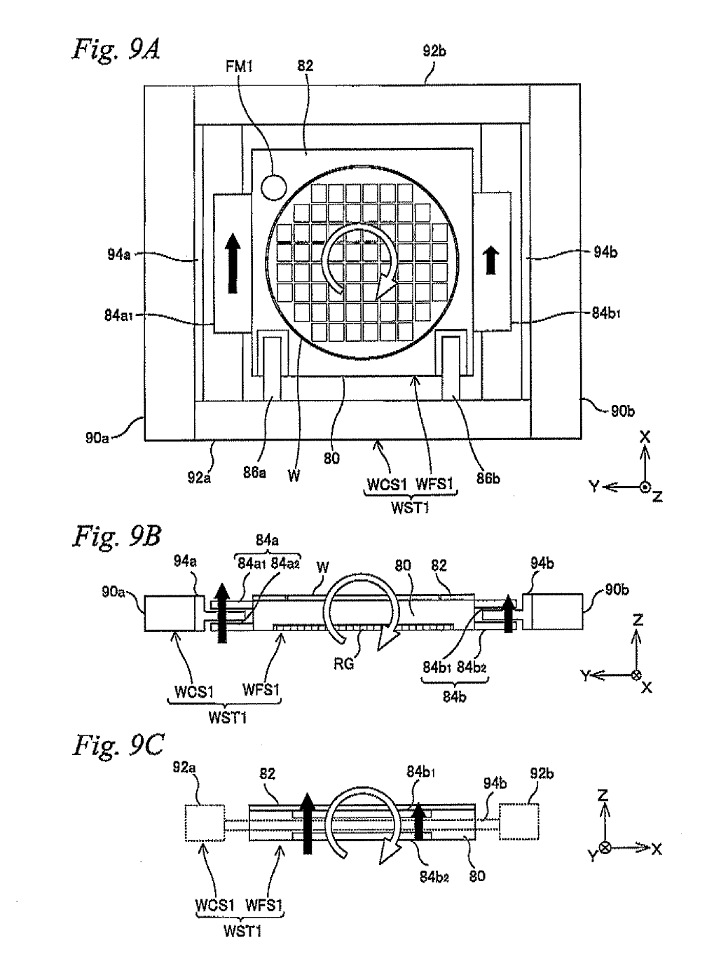

Further, as shown in FIG. 9A, for example, main controller 20 can make fine movement stage WFS1 rotate around the Z-axis (θz rotation) (refer to the outlined arrow in FIG. 9A) by applying a drive force (thrust) in the Y-axis direction having a different magnitude to both mover section 84a and mover section 84b (refer to the black arrow in FIG. 9A). Incidentally, in contrast with FIG. 9A, by making the drive force applied to mover section 84a on the −Y side larger than the +Y side, fine movement stage WFS1 can be made to rotate counterclockwise with respect to the Z-axis.

Further, as shown in FIG. 9B, main controller 20 can make fine movement stage WFS1 rotate around the X-axis (θx drive) (refer to the outlined arrow in FIG. 9B), by applying a different levitation force to both mover section 84a and mover section 84b (refer to the black arrow in FIG. 9B). Incidentally, in contrast with FIG. 9B, by making the levitation force applied to mover section 84b larger than the mover section 84a side, fine movement stage WFS1 can be made to rotate counterclockwise with respect to the X-axis.

Further, as shown in FIG. 9C, for example, main controller 20 can make fine movement stage WFS1 rotate around the Y-axis (θy drive) (refer to the outlined arrow in FIG. 9C), by applying a different levitation force on the + side and the − side in the X-axis direction (refer to the black arrow in FIG. 9C) to each of the mover sections 84a and 84b. Incidentally, in contrast with FIG. 9C, by making the levitation force applied to mover section 84a (and 84b) on the +X side smaller than the levitation force on the −X side, fine movement stage WFS1 can be made to rotate counterclockwise with respect to the Y-axis.

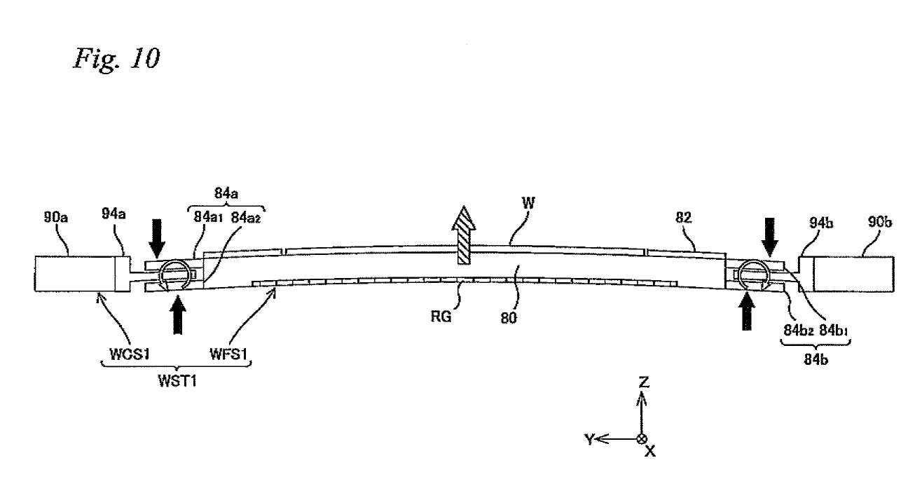

Further, in the embodiment, by supplying electric current to the two lines of coils 155 and 157 (refer to FIG. 6) placed inside stator section 94a in directions opposite to each other when applying the levitation force to fine movement stage WFS1, for example, main controller 20 can apply a rotational force (refer to the outlined arrow in FIG. 10) around the X-axis simultaneously with the levitation force (refer to the black arrow in FIG. 10) with respect to mover section 84a, as shown in FIG. 10. Similarly, by supplying electric current to the two lines of coils 155 and 157 placed inside stator section 94b in directions opposite to each other when applying the levitation force to fine movement stage WFS1, for example, main controller 20 can apply a rotational force around the X-axis simultaneously with the levitation force with respect to mover section 84b.

In other words, in the embodiment, a first driving section 164a (refer to FIG. 13) is configured by coil unit CUa, which configures a part of fine movement stage driving system 64A, and magnet units 98a₁ and 98a₂ that applies a driving force in directions of six degrees of freedom (X, Y, Z, θx, θy, and θz) with respect to the +Y side end of fine movement stage WFS1, and a second driving section 164b (refer to FIG. 13) is configured by coil unit CUb, which configures a part of fine movement stage driving system 64A, and magnet units 98b₁ and 98b₂ that applies a driving force in directions of six degrees of freedom (X, Y, Z, θx, θy, and θz) with respect to the −Y side end of fine movement stage WFS1.

As it can be seen from the description above, in the embodiment, fine movement stage driving system 64A (first and second driving sections) supports fine movement stage WFS1 by levitation in a non-contact state with respect to coarse movement stage WCS1, and can also drive fine movement stage WFS1 in a non-contact manner in directions of six degrees of freedom (X, Y, Z, θx, θy, and θz) with respect to coarse movement stage WCS1.

Further, by applying a rotational force around the X-axis (a force in the ex direction) to each of the pair of mover sections 84a and 84b via the first and second driving sections 164a and 164b in directions opposite to each other, main controller 20 can deflect the center in the Y-axis direction of fine movement stage WFS1 in the +Z direction or the −Z direction (refer to the hatched arrow in FIG. 10). Accordingly, as shown in FIG. 10, by bending the center of fine movement stage WFS1 in the +Z direction (in a convex shape), the deflection in the middle part of fine movement stage WFS1 (main body section 80) in the Y-axis direction due to the self-weight of wafer W and main body section 80 can be canceled out, and degree of parallelization of the wafer W surface with respect to the XY plane (horizontal surface) can be secured. This is particularly effective, in the case such as when the diameter of wafer W becomes large and fine movement stage WFS1 also becomes large.

Further, when wafer W is deformed by its own weight and the like, while there is a risk that an area including an irradiation area (exposure area IA) of illumination light IL on the surface of wafer W mounted on fine movement stage WFS1 will no longer be within the range of the depth of focus of projection optical system by applying a rotational force around the X-axis in directions opposite to each other to the pair of mover sections 84a and 84b, respectively, via the first and second driving sections described above similar to when main controller 20 bends the center in the Y-axis direction of fine movement stage WFS1 in the +Z direction, wafer W can be deformed to be substantially flat, and the area including exposure area IA can be made to fall within the range of the depth of focus of projection optical system PL. Incidentally, while FIG. 10 shows an example where fine movement stage WFS1 is bent in the +Z direction (a convex shape), fine movement stage WFS1 can also be bent in a direction opposite to this (a concave shape) by controlling the direction of the electric current supplied to the coils.

On the wafer stage WST2 side as well, a fine movement stage driving system 64B (refer to FIG. 13) is configured as in fine movement stage driving system 64A similar to the wafer stage WST1 side, and fine movement stage WFS2 is driven as in the manner described above with respect to coarse movement stage WCS2 by fine movement stage driving system 64B.

Fine movement stage WFS1 is movable in the X-axis direction, with a longer stroke compared with the directions of the other five degrees of freedom, along stator sections 94a and 94b arranged extending in the X-axis direction. The same applies to fine movement stage WFS2.

With the configuration as described above, fine movement stage WFS1 is movable in the directions of six degrees of freedom with respect to coarse movement stage WCS1. Further, on this operation, the law of action and reaction (the law of conservation of momentum) that is similar to the previously described one holds owing to the action of a reaction force by drive of fine movement stage WFS1. More specifically, coarse movement stage WCS1 functions as the countermass of fine movement stage WFS1, and coarse movement stage WCS1 is driven in a direction opposite to fine movement stage WFS1. Fine movement stage WFS2 and coarse movement stage WCS2 has the similar relation.

Incidentally, in the embodiment, as fine movement stage driving systems 64A and 64B, the planar motors of a moving magnet type are used, but the planar motors are not limited to this, and planar motors of a moving coil type in which the coil units are placed at the mover sections of the fine movement stages and the magnetic units are placed at the stator sections of the coarse movement stages can also be used.

Between coupling member 92a of coarse movement stage WCS1 and main section 80 of fine movement stage WFS1, as shown in FIG. 4A, a pair of tubes 86a and 86b used to transmit the power usage, which is supplied from the outside to coupling member 92a via a tube carrier, to fine movement stage WFS1 are installed. One ends of tubes 86a and 86b are connected to the side surface on the +X side of coupling member 92a and the other ends are connected to the inside of main section 80, respectively via a pair of recessed sections 80a (refer to FIG. 4C) with a predetermined depth each of which is formed from the end surface on the −X side toward the +X direction with a predetermined length, on the upper surface of main section 80. As shown in FIG. 4C, tubes 86a and 86b are configured not to protrude above the upper surface of fine movement stage WFS1. Also between coupling member 92a of coarse movement stage WCS2 and main section 80 of fine movement stage WFS2, as shown in FIG. 2, a pair of tubes 86a and 86b used to transmit the power usage, which is supplied from the outside to coupling member 92a via a tube carrier, to fine movement stage WFS2 is installed.

Power usage, here, is a generic term of power for various sensors and actuators such as motors, coolant for temperature adjustment to the actuators, pressurized air for air bearings and the like which is supplied from the outside to coupling member 92a via the tube carrier (not shown). In the case where a vacuum suction force is necessary, the force for vacuum (negative pressure) is also included in the power usage.

The tube carrier is arranged in a pair corresponding to wafer stages WST1 and WST2, respectively, and is actually placed each on a step portion formed at the end on the −X side and the +X side of base board 12 shown in FIG. 3, and is driven in the Y-axis direction following wafer stages WST1 and WST2 by actuators such as linear motors on the step portion.

Next, a measuring system that measures positional information of wafer stages WST1 and WST2 is described. Exposure apparatus 100 has a fine movement stage position measuring system 70 (refer to FIG. 13) to measure positional information of fine movement stages WFS1 and WFS2 and coarse movement stage position measuring systems 68A and 68B (refer to FIG. 13) to measure positional information of coarse movement stages WCS1 and WCS2 respectively.

Fine movement stage position measuring system 70 has a measurement bar 71 shown in FIG. 1. Measurement bar 71 is placed below first sections 14A₁ and 14B₁ that the pair of surface plates 19A and 14B respectively have, as shown in FIG. 3. As is obvious from FIGS. 1 and 3, measurement bar 71 is made up of a beam-like member having a rectangular sectional shape with the Y-axis direction serving as its longitudinal direction, and both ends in the longitudinal direction are each fixed to main frame BD in a suspended state via a suspended member 74. More specifically, main frame BD and measurement bar 71 are integrated.

The +Z side half (upper half) of measurement bar 71 is placed between second section 14A₂ of surface plate 14A and second section 14B₂ of surface plate 1413, and the −Z side half (lower half) is housed inside recessed section 12a formed at base board 12. Further, a predetermined clearance is formed between measurement bar 71 and each of surface plates 14A and 143 and base board 12, and measurement bar 71 is in a state noncontact with the members other than main frame BD. Measurement bar 71 is formed by a material with a relatively low coefficient of thermal expansion (e.g. invar, ceramics, or the like). Incidentally, the shape of measurement bar 71 is not limited in particular. For example, it is also possible that the measurement member has a circular cross section (a cylindrical shape), or a trapezoidal or triangle cross section. Further, the measurement bar does not necessarily have to be formed by a longitudinal member such as a bar-like member or a beam-like member.

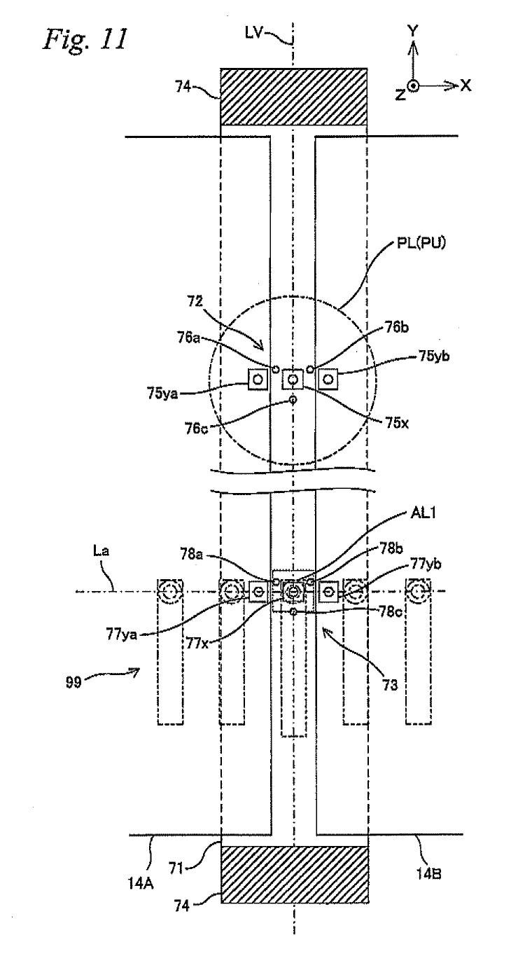

At measurement bar 71, as shown in FIG. 11, a first measurement head group 72 used when measuring positional information of the fine movement stage (WFS1 or WFS2) located below projection unit PU and a second measurement head group 73 used when measuring positional information of the fine movement stage (WFS1 or WFS2) located below alignment device 99 are arranged. Incidentally, alignment systems AL1 and AL2₁ to AL2₄ are shown in virtual lines (two-dot chain lines) in FIG. 11 in order to make the drawing easy to understand. Further, in FIG. 11, the reference signs of alignment systems AL2₁ to AL2₄ are omitted.

As shown in FIG. 11, the first measurement head group 72 is placed below projection unit PU and includes a one-dimensional encoder head for X-axis direction measurement (hereinafter, shortly described as an X head or an encoder head) 75x, a pair of one-dimensional encoder heads for Y-axis direction measurement (hereinafter, shortly described as Y heads or encoder heads) 75ya and 75yb, and three Z heads 76a, 76b and 76c.

X head 75x, Y heads 75ya and 75yb and the three Z heads 76a to 76c are placed in a state where their positions do not vary, inside measurement bar 71. X head 75x is placed on reference axis LV, and Y heads 75ya and 75yb are placed at the same distance away from X head 75x, on the −X side and the +X side, respectively. In the embodiment, as each of the three encoder heads 75x, 75ya and 75yb, a diffraction interference type head is used which is a head having a configuration in which a light source, a photodetection system (including a photodetector) and various types of optical systems are unitized, similar to the encoder head disclosed in, for example, PCT International Publication No. 2007/083758 (the corresponding U.S. Patent Application Publication No. 2007/0288121) and the like.

When wafer stage WST1 (or WST2) is located directly under projection optical system PL (refer to FIG. 1), X head 75x and Y heads 75ya and 75yb each irradiate a measurement beam on grating RG (refer to FIG. 4B) placed on the lower surface of fine movement stage WFS1 (or WFS2), via a gap between surface plate 14A and surface plate 14B or a light-transmitting section (e.g. an opening) formed at first section 14A₁ of surface plate 14A and first section 14B₁ of surface plate 14B. Further, X head 75x and Y heads 75ya and 75yb respectively receive diffraction light from grating RG, thereby obtaining positional information within the XY plane (also including rotational information in the z direction) of fine movement stage WFS1 (or WFS2). More specifically, an X liner encoder 51 (refer to FIG. 13) is configured of X head 75x that measures the position of fine movement stage WFS1 (or WFS2) in the X-axis direction using the X diffraction grating that grating RG has. And, a pair of Y liner encoders 52 and 53 (refer to FIG. 13) are configured of the pair of Y heads 75ya and 75yb that measure the position of fine movement stage WFS1 (or WFS2) in the Y-axis direction using the Y diffraction grating of grating RG. The measurement value of each of X head 75x and Y heads 75ya and 75yb is supplied to main controller 20 (refer to FIG. 13), and main controller 20 measures (computes) the position of fine movement stage WFS1 (or WFS2) in the X-axis direction based on the measurement value of X head 75x, and the position of fine movement stage WFS1 (or WFS2) in the Y-axis direction based on the average value of the measurement values of the pair of Y head 75ya and 75yb. Further, main controller 20 measures (computes) the position in the θz direction (rotational amount around the Z-axis) of fine movement stage WFS1 (or WFS2) using the measurement value of each of the pair of Y linear encoders 52 and 53.

In this case, an irradiation point (detection point), on grating RG, of the measurement beam irradiated from X head 75x coincides with the exposure position that is the center of exposure area IA (refer to FIG. 1) on wafer W. Further, a midpoint of a pair of irradiation points (detection points), on grating RG, of the measurement beams respectively irradiated from the pair of Y heads 75ya and 75yb coincides with the irradiation point (detection point), on grating RG, of the measurement beam irradiated from X head 75x. Main controller 20 computes positional information of fine movement stage WFS1 (or WFS2) in the Y-axis direction based on the average of the measurement values of the two Y heads 75ya and 75yb. Therefore, the positional information of the fine movement stage (WFS1 or WFS2) in the Y-axis direction is substantially measured at the exposure position that is the center of irradiation area (exposure area) IA of illumination light IL irradiated on wafer W. More specifically, the measurement center of X head 75x and the substantial measurement center of the two Y heads 75ya and 75yb coincide with the exposure position. Consequently, by using X linear encoder 51 and Y linear encoders 52 and 53, main controller 20 can perform measurement of the positional information within the XY plane (including the rotational information in the z direction) of fine movement stage WFS1 (or WFS2) directly under (on the back side of) the exposure position at all times.

As each of Z heads 76a to 76c, for example, a head of a displacement sensor by an optical method similar to an optical pickup used in a CD drive device or the like is used. The three Z heads 76a to 76c are placed at the positions corresponding to the respective vertices of an isosceles triangle (or an equilateral triangle). Z heads 76a to 76c each irradiate the lower surface of fine movement stage WFS1 (or WFS2) with a measurement beam parallel to the Z-axis from below, and receive reflected light reflected by the surface of the plate on which grating RG is formed (or the formation surface of the reflective diffraction grating). Accordingly, Z heads 76a to 76c configure a surface position measuring system 54 (refer to FIG. 13) that measures the surface position (position in the Z-axis direction) of fine movement stage WFS1 (or WFS2) at the respective irradiation points. The measurement values of each of the three Z heads 76a to 76c are supplied to main controller 20 (refer to FIG. 13).

The center of gravity of the isosceles triangle (or the equilateral triangle) whose vertices are at the three irradiation points on grating RG of the measurement beams respectively irradiated from the three Z heads 76a to 76c coincides with the exposure position that is the center of exposure area IA (refer to FIG. 1) on wafer W. Consequently, based on the average value of the measurement values of the three Z heads 76a to 76c, main controller 20 can acquire positional information in the Z-axis direction (surface position information) of fine movement stage WFS1 (or WFS2) directly under the exposure position at all times. Further, main controller 20 measures (computes) the rotational amount in the θx direction and the θy direction, in addition to the position in the Z-axis direction of fine movement stage WFS1 (or WFS2) using the measurement values of the three Z heads 76a to 76c.

The second measurement head group 73 has X head 77x that configures X liner encoder 55 (refer to FIG. 13), a pair of Y heads 77ya and 77yb that configure a pair of Y linear encoders 56 and 57 (refer to FIG. 33), and three Z heads 78a, 78b and 78c that configure surface position measuring system 58 (refer to FIG. 13). The respective positional relations of the pair of Y heads 77ya and 77yb and the three Z heads 78a to 78c with X head 77x serving as a reference are similar to the respective positional relations described above of the pair of Y heads 75ya and 75yb and the three Z heads 76a to 76c with X head 75x serving as a reference. An irradiation point (detection point) on grating RG, of the measurement beam irradiated from X head 77x coincides with the detection center of primary alignment system ALL. More specifically, the measurement center of X head 77x and the substantial measurement center of the two Y heads 77ya and 77yb coincide with the detection center of primary alignment system AL1. Consequently, main controller 20 can perform measurement of positional information within the XY plane and surface position information of fine movement stage WFS2 (or WFS1) at the detection center of primary alignment system AL1 at all times.

Incidentally, while each of X heads 75x and 77x and Y heads 75ya, 75yb, 77ya and 77yb of the embodiment has the light source, the photodetection system (including the photodetector) and the various types of optical systems (none of which are illustrated) that are unitized and placed inside measurement bar 71, the configuration of the encoder head is not limited thereto. For example, the light source and the photodetection system can be placed outside the measurement bar. In such a case, the optical systems placed inside the measurement bar, and the light source and the photodetection system are connected to each other via, for example, an optical fiber or the like. Further, a configuration can also be employed in which the encoder head is placed outside the measurement bar and only a measurement beam is guided to the grating via an optical fiber placed inside the measurement bar. Further, the rotational information of the wafer in the z direction can be measured using a pair of the X liner encoders (in this case, there should be one Y linear encoder). Further, the surface position information of the fine movement stage can be measured using, for example, an optical interferometer. Further, instead of the respective heads of first measurement head group 72 and second measurement head group 73, three encoder heads in total, which include at least one XZ encoder head whose measurement directions are the X-axis direction and the Z-axis direction and at least one YZ encoder head whose measurement directions are the Y-axis direction and the Z-axis direction, can be arranged in the placement similar to that of the X head and the pair of Y heads described earlier.

When wafer stage WST1 moves between exposure station 200 and measurement station 300 on surface plate 14A, coarse movement stage position measuring system 68A (refer to FIG. 13) measures positional information of coarse movement stage WCS1 (wafer stage WST1). The configuration of coarse movement stage position measuring system 68A is not limited in particular, and includes an encoder system or an optical interferometer system (it is also possible to combine the optical interferometer system and the encoder system). In the case where coarse movement stage position measuring system 68A includes the encoder system, for example, a configuration can be employed in which the positional information of coarse movement stage WCS1 is measured by irradiating a scale (e.g. two-dimensional grating) fixed (or formed) on the upper surface of coarse movement stage WCS1 with measurement beams from a plurality of encoder heads fixed to main frame BD in a suspended state along the movement course of wafer stage WST1 and receiving the diffraction light of the measurement beams. In the case where coarse movement stage measuring system 68A includes the optical interferometer system, a configuration can be employed in which the positional information of wafer stage WST1 is measured by irradiating the side surface of coarse movement stage WCS1 with measurement beams from an X optical interferometer and a Y optical interferometer that have a measurement axis parallel to the X-axis and a measurement axis parallel to the Y-axis respectively and receiving the reflected light of the measurement beams.

Coarse movement stage position measuring system 68B (refer to FIG. 13) has the configuration similar to coarse movement stage position measuring system 68A, and measures positional information of coarse movement stage WCS2 (wafer stage WST2). Main controller 20 respectively controls the positions of coarse movement stages WCS1 and WCS2 (wafer stages WST1 and WST2) by individually controlling coarse movement stage driving systems 62A and 62B, based on the measurement values of coarse movement stage position measuring systems 68A and 68B.

Next, relative position measuring systems 66A and 66B (refer to FIG. 13), which is used for measuring the relative positional information between fine movement stages WFS1, WFS2 and coarse movement stages WCS1, WCS2 will be described. Relative position measuring systems 66A and 66B, as representatively shown by relative position measuring system 66A in FIG. 13, are configured of a first encoder system 17a and a second encoder system 17b.

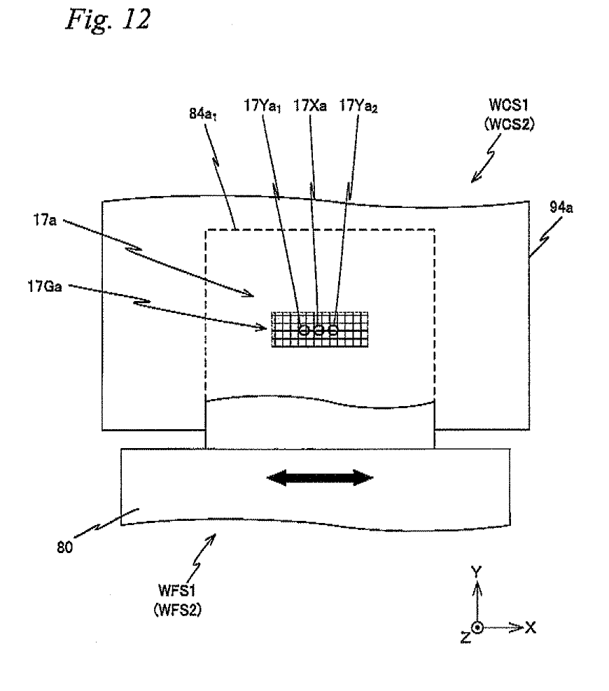

FIG. 12 shows a placement of three encoder heads 17Ya₁, 17Ya₂, 17Xa and a grating 17Ga configuring the first encoder system 17a. Here, grating RG is a two-dimensional grating including a reflection diffraction grating (X diffraction grating) whose periodic direction is in the X-axis direction, and a reflection grating (Y diffraction grating) whose periodic direction is in the Y-axis direction.

As shown in FIG. 12, grating 17Ga is placed on the −Z surface (of plate-like member 84a₁) of mover section 84a fixed to the +Y end (of main section 80) of fine movement stage WFS1. Grating 17Ga has a rectangle tabular shape whose longitudinal direction is in the X-axis direction. Here, the length of grating 17Ga in the X-axis direction, for example, is approximately equal to the difference between the width of main section 80 of fine movement stage WFS1 and the separation distance of coupling members 92a and 92b of coarse movement stage WCS1. Meanwhile, the width in the Y-axis direction is approximately equal to the difference between the width of main section 80 of fine movement stage WFS1 and the separation distance of stator sections 94a and 94b fixed to coarse movement stage WCS1.

Encoder heads 17Ya₁ and 17Ya₂, and 17Xa are one-dimensional encoder heads whose measurement directions are in the Y-axis direction and the X-axis direction, respectively. Here, encoder heads 17Ya₁ and 17Ya₂ will be referred to as Y heads, and encoder head 17Xa will be referred to as an X head. In the embodiment, as Y heads 17Ya₁ and 17Ya₂, and X head 17Xa, heads with a configuration similar to heads 75x, 75ya, and 75yb previously described are employed.

As shown in FIG. 12, Y heads 17Ya₁ and 17Ya₂, and X head 17Xa are placed embedded in stator section 94a fixed to coarse movement stage WCS1, with the outgoing section of the measurement beam facing the +Z side, Now, in a state where fine movement stage WFS1 is supported by coarse movement stage WCS1 substantially in its center, X head 17Xa faces the center of grating 17Ga. To be more precise, an irradiation point of the measurement beam of X head 17Xa coincides with the center of grating 17Ga. Y heads 17Ya₁ and 17Ya₂ are separated at an equal distance on the ±X side, respectively, from X head 17Xa. More specifically, on grating 17Ga, the irradiation points of the measurement beams of Y heads 17Ya₁ and 17Ya₂ are set apart at an equal distance on the ±X sides, with the irradiation point of the measurement beam of X head 17Xa as the center.

The separation distance of Y heads 17Ya₁ and 17Ya₂ in the X-axis direction, as an example, is substantially equal to (somewhat shorter than) the difference between twice the length of grating 17Ga and a movement stroke of fine movement stage WFS1 with respect to coarse movement stage WCS1. Therefore, in the case fine movement stage WFS1 is driven in the +X direction with respect to coarse movement stage WCS1 and reaches the +X end of the movement stroke, Y heads 17Ya₁ and 17Ya₂ and X head 17Xa face the vicinity of the −X end of grating 17Ga. Further, in the case fine movement stage WFS1 is driven in the −X direction with respect to coarse movement stage WCS1 and reaches the −X end of the movement stroke, Y heads 17Ya₁ and 17Ya₂ and X head 17Xa face the vicinity of the +X end of grating 17Ga. More specifically, in the total movement strokes of fine movement stage WFS1, Y heads 17Ya₁ and 17Ya₂, and X head 17Xa always face grating 17Ga.

Y heads 17Ya₁ and 17Ya₂ irradiate measurement beams on grating 17Ga facing the X heads, and by receiving the return lights (diffraction lights), measure the relative positional information of fine movement stage WFS1 in the Y-axis direction with respect to coarse movement stage WCS1. Similarly, X head 17Xa measures the relative positional information of fine movement stage WFS1 in the X-axis direction with respect to coarse movement stage WCS1. These measurements results are supplied to main controller 20 (refer to FIG. 13).

Main controller 20 obtains the relative positional information in the XY plane between fine movement stage WFS1 and coarse movement stage WCS1, using the measurement results which have been supplied. Here, as is previously described, the irradiation points (more specifically, measurement points) of the measurement beams of Y heads 17Ya₁ and 17Ya₂ on grating 17Ga are distanced apart in the ±X direction, with the irradiation point (more specifically, the measurement point) of X head 17Xa as the center. Accordingly, the relative positional information of fine movement stage WFS1 in the Y-axis direction and the θz direction, with the measurement point of X head 17Xa serving as a reference point, is obtained from the measurement results of Y heads 17Ya₁ and 17Ya₂. Further, the relative positional information of fine movement stage WFS1 in the X-axis direction is obtained from the measurement results of X head 17Xa.

The second encoder system 17b is configured of two Y heads and one X head and a two-dimensional grating, similar to the first encoder system 17a. The two Y heads and one X head are placed on stator section 94b fixed to coarse movement stage WCS1, and the two-dimensional grating is placed on the −Z surface (of plate-like member 84b₁) of mover section 84b fixed to the −Y end (of main section 80) of fine movement stage WFS1. These placements are symmetric to Y heads 17Ya₁ and 17Ya₂, and X head 17Xa and grating 17Ga configuring the first encoder system 17a, with respect to the X-axis which passes through the center of main section 80.

The measurement results of the two Y heads and one X head configuring the second encoder system 17b is also supplied to main controller 20 (refer to FIG. 13). Main controller 20 obtains the relative positional information in the XY plane between fine movement stage WFS1 and coarse movement stage WCS1, using the measurement results which have been supplied. Main controller 20 then finally decides the relative positional information of fine movement stage WFS1 with respect to coarse movement stage WCS1, for example, by averaging, based on the two relative positional information obtained from the measurement results of the first and the second encoder systems 17a and 17b.

Relative position measuring system 66B which measures the relative positional information between fine movement stage WFS2 and coarse movement stage WCS2 is configured in a similar manner as relative position measuring system 66A described above.

Main controller 20 obtains positional information (including the positional information in the θz direction) of coarse movement stages WCS1 and WCS2 in the XY plane, from the positional information of fine movement stages WFS1 and WFS2 measured using fine movement stage position measuring system 70 and from the relative positional information between fine movement stages WFS1 and WFS2 and coarse movement stages WCS1 and WCS2 which are measured using relative position measuring systems 66A and 66g. And, based on the results, main controller 20 controls the position of coarse movement stages WCS1 and WCS2. Especially at the time of exposure operation by the step-and-scan method to wafer W, main controller 20 steps and drives coarse movement stages WCS1 and WCS2 in a non-scanning direction on the movement operation (stepping operation between shots) between shot areas.

Incidentally, the relative position measuring system is not limited to the configuration described above. For example, the relative position measuring system can be configured using, for example, a gap sensor including a capacitance sensor instead of an encoder system.

Furthermore, although it is omitted in FIG. 1, in exposure apparatus 100 of the embodiment, a focus sensor AF (refer to FIG. 13) which measures the position and the tilt of the wafer W surface in the Z-axis direction is provided at exposure station 200. Focus sensor AF, for example, consists of a multiple point focal position detection system of an oblique incidence method as the one disclosed in, for example, U.S. Pat. No. 5,448,332 and the like. Measurement results of focus sensor AF are supplied to main controller 20. During the exposure operation, main controller 20 drives fine movement stages WFS1 and WFS2 based on the measurement results in the Z-axis direction, the θx direction, and the θy direction via fine movement stage driving systems 64A, and 64B, and controls (performs focus leveling control of) the position and tilt of wafer W in the optical axis direction of projection optical system PL.

FIG. 13 shows a block diagram showing an input/output relation of main controller 20, which centrally configures a control system of exposure apparatus 100 and has overall control over each part. Main controller 20 includes a workstation (or a microcomputer) and the like, and performs overall control of the respective components of exposure apparatus 100 such as local liquid immersion device 8, surface plate driving systems 60A and 60B, coarse movement stage driving systems 62A and 62B, and fine movement stage driving systems 64A and 64B.

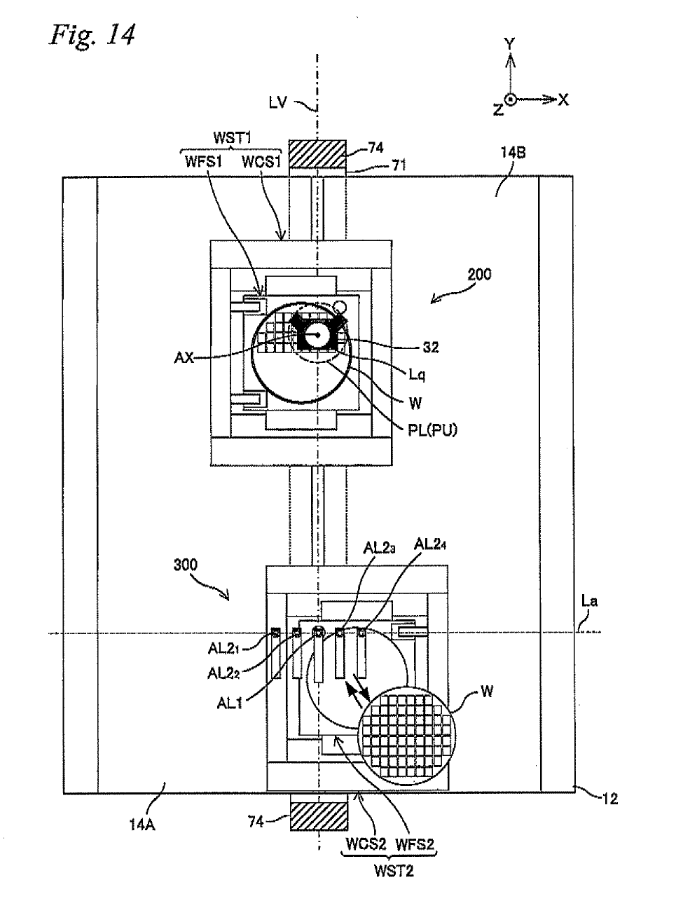

Next, a parallel processing operation using the two wafer stages WST1 and WST2 is described with reference to FIGS. 14 to 18. Note that during the operation below, main controller 20 controls liquid supply device 5 and liquid recovery device 6 as described earlier and a constant quantity of liquid Lq is held directly under tip lens 191 of projection optical system PL, and thereby a liquid immersion area is formed at all times.

FIG. 14 shows a state where exposure by a step-and-scan method is performed on wafer W mounted on fine movement stage WFS1 of wafer stage WST1 in exposure station 200, and in parallel with this exposure, wafer exchange is performed between a wafer carrier mechanism (not shown) and fine movement stage WFS2 of wafer stage WST2 at the second loading position.

Main controller 20 performs the exposure operation by a step-and-scan method by repeating an inter-shot movement (stepping between shots) operation of moving wafer stage WST1 to a scanning starting position (acceleration starting position) for exposure of each shot area on wafer W, based on the results of wafer alignment (e.g. information obtained by converting an arrangement coordinate of each shot area on wafer W obtained by an Enhanced Global Alignment (EGA) into a coordinate with the second fiducial mark on measurement plate FM1 serving as a reference) and reticle alignment and the like that have been performed beforehand, and a scanning exposure operation of transferring a pattern formed on reticle R onto each shot area on wafer W by a scanning exposure method. During this step-and-scan operation, surface plates 14A and 14B exert the function as the countermasses, as described previously, according to movement of wafer stage WST1, for example, in the Y-axis direction, during scanning exposure. Further, main controller 20 gives the initial velocity to coarse movement stage WCS1 when driving fine movement stage WFS1 in the X-axis direction for the stepping operation between shots, and thereby coarse movement stage WCS1 functions as a local countermass with respect to fine movement stage WFS1. On this operation, an initial velocity can be given to coarse movement stage WCS1 which makes the stage move in the stepping direction at a constant speed. Such a driving method is described in, for example, U.S. Patent Application Publication No. 2008/0143994. Consequently, the movement of wafer stage WST1 (coarse movement stage WCS1 and fine movement stage WFS1) does not cause vibration of surface plates 14A and 14B and does not adversely affect wafer stage WST2.

The exposure operations described above are performed in a state where liquid Lq is held in the space between tip lens 191 and wafer W (wafer W and plate 82 depending on the position of a shot area), or more specifically, by liquid immersion exposure.

In exposure apparatus 100 of the embodiment, during a series of the exposure operations described above, main controller 20 measures the position of fine movement stage WFS1 using first measurement head group 72 of fine movement stage position measuring system 70 and controls the position of fine movement stage WFS1 (wafer W) based on this measurement result.

The wafer exchange is performed by unloading a wafer that has been exposed from fine movement stage WFS2 and loading a new wafer onto fine movement stage WFS2 by the wafer carrier mechanism that is not illustrated, when fine movement stage WFS2 is located at the second loading position. In this case, the second loading position is a position where the wafer exchange is performed on wafer stage WST2, and in the embodiment, the second loading position is to be set at the position where fine movement stage WFS2 (wafer stage WST2) is located such that measurement plate FM2 is positioned directly under primary alignment system AL1.

During the wafer exchange described above, and after the wafer exchange, while wafer stage WST2 stops at the second loading position, main controller 20 executes reset (resetting of the origin) of second measurement head group 73 of fine movement stage position measuring system 70, or more specifically, encoders 55, 56 and 57 (and surface position measuring system 58), prior to start of wafer alignment (and the other pre-processing measurements) with respect to the new wafer W.

When the wafer exchange (loading of the new wafer W) and the reset of encoders 55, 56 and 57 (and surface position measuring system 58) have been completed, main controller 20 detects the second fiducial mark on measurement plate FM2 using primary alignment system AL1. Then, main controller 20 detects the position of the second fiducial mark with the index center of primary alignment system AL1 serving as a reference, and based on the detection result and the result of position measurement of fine movement stage WFS2 by encoders 55, 56 and 57 at the time of the detection, computes the position coordinate of the second fiducial mark in the orthogonal coordinate system (alignment coordinate system) with reference axis La and reference axis LV serving as coordinate axes.

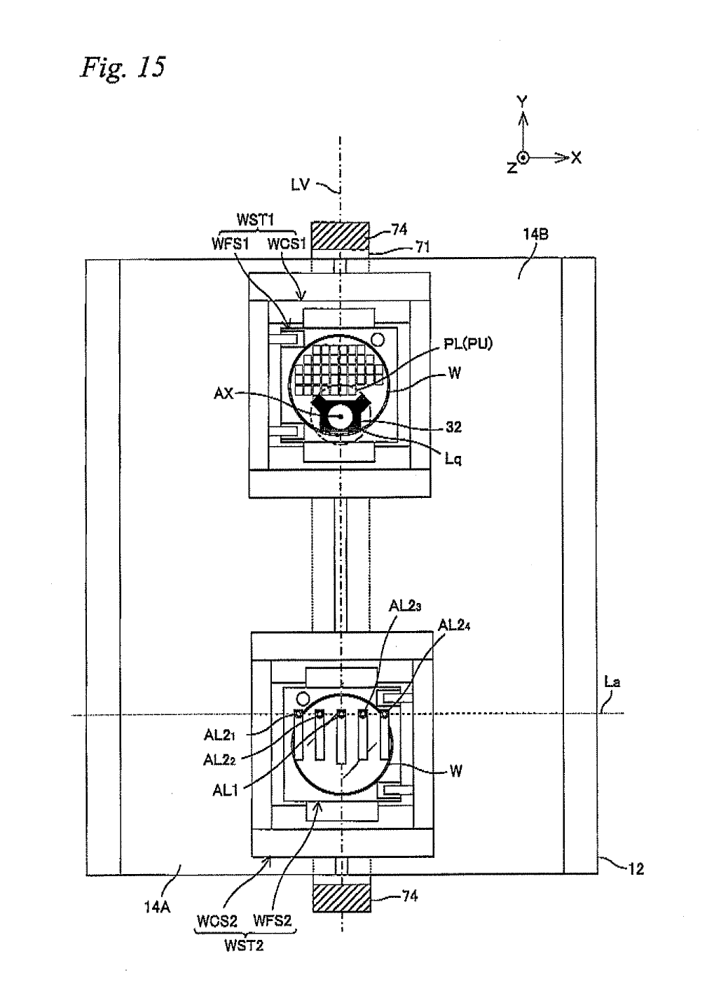

Next, main controller 20 performs the EGA while measuring the position coordinate of fine movement stage WFS2 (wafer stage WST2) in the alignment coordinate system using encoders 55, 56 and 57 (refer to FIG. 15). To be more specific, as disclosed in, for example, U.S. Patent Application Publication No. 2008/0088843 and the like, main controller 20 moves wafer stage WST2, or more specifically, coarse movement stage WCS2 that supports fine movement stage WFS2 in, for example, the Y-axis direction, and sets the position of fine movement stage WFS2 at a plurality of positions in the movement course, and at each position setting, detects the position coordinates, in the alignment coordinate system, of alignment marks at alignment shot areas (sample shot areas) using at least one of alignment systems AL1 and AL2₂ and AL2₄. FIG. 15 shows a state of wafer stage WST2 when the detection of the position coordinates of the alignment marks in the alignment coordinate system is performed.

In this case, in conjunction with the movement operation of wafer stage WST2 in the Y-axis direction described above, alignment systems AL1 and AL2₂ to AL2₄ respectively detect a plurality of alignment marks (sample marks) disposed along the X-axis direction that are sequentially placed within the detection areas (e.g. corresponding to the irradiation areas of detection light). Therefore, on the measurement of the alignment marks described above, wafer stage WST2 is not driven in the X-axis direction.

Then, based on the position coordinates of the plurality of alignment marks arranged at the sample shot areas on wafer W and the design position coordinates, main controller 20 executes statistical computation (EGA computation) disclosed in, for example, U.S. Pat. No. 4,760,617 and the like, and computes the position coordinates (arrangement coordinates) of the plurality of shot areas in the alignment coordinate system.

Further, in exposure apparatus 100 of the embodiment, since measurement station 300 and exposure station 200 are spaced apart, main controller 20 subtracts the position coordinate of the second fiducial mark that has previously been detected from the position coordinate of each of the shot areas on wafer W that has been obtained as a result of the wafer alignment, thereby obtaining the position coordinates of the plurality of shot areas on wafer W with the position of the second fiducial mark serving as the origin.

Normally, the above-described wafer exchange and wafer alignment sequence is completed earlier than the exposure sequence. Therefore, when the wafer alignment has been completed, main controller 20 drives wafer stage WST2 in the +X direction to move wafer stage WST2 to a predetermined standby position on surface plate 14B. In this case, when wafer stage WST2 is driven in the +X direction, fine movement stage WFS2 moves out of a measurable range of fine movement stage position measuring system 70 (i.e. the respective measurement beams irradiated from second measurement head group 73 move off from grating RG). Therefore, based on the measurement values of fine movement stage position measuring system 70 (encoders 55, 56 and 57) and the measurement values of relative position measuring system 66B, main controller 20 obtains the position of coarse movement stage WCS2, and afterward, controls the position of wafer stage WST2 based on the measurement values of coarse movement stage position measuring system 68B. More specifically, position measurement of wafer stage WST2 within the XY plane is switched from the measurement using encoders 55, 56 and 57 to the measurement using coarse movement stage position measuring system 68B. Then, main controller 20 makes wafer stage WST2 wait at the predetermined standby position described above until exposure on wafer W on fine movement stage WFS1 is completed.

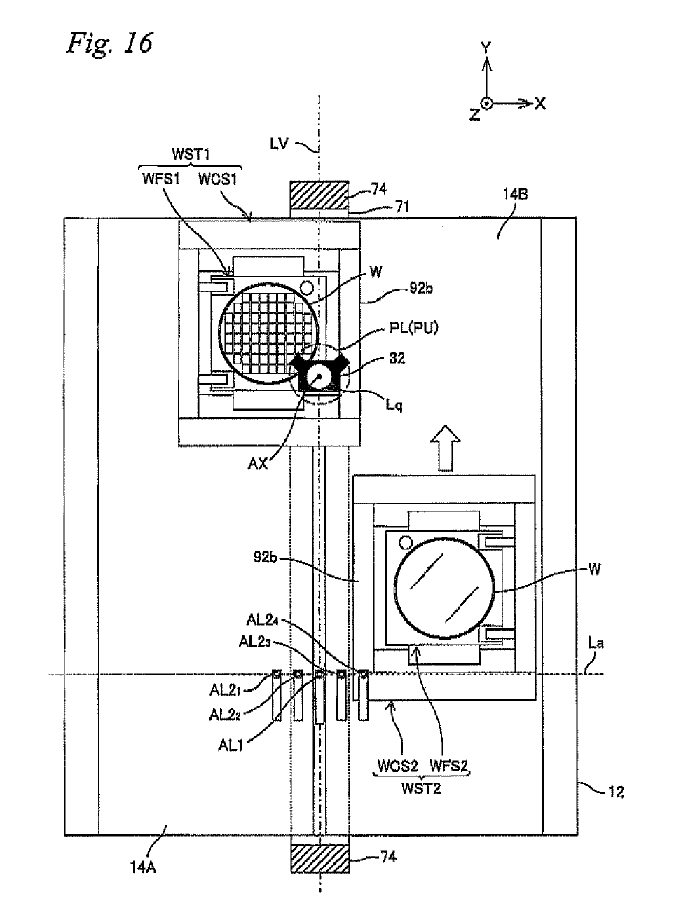

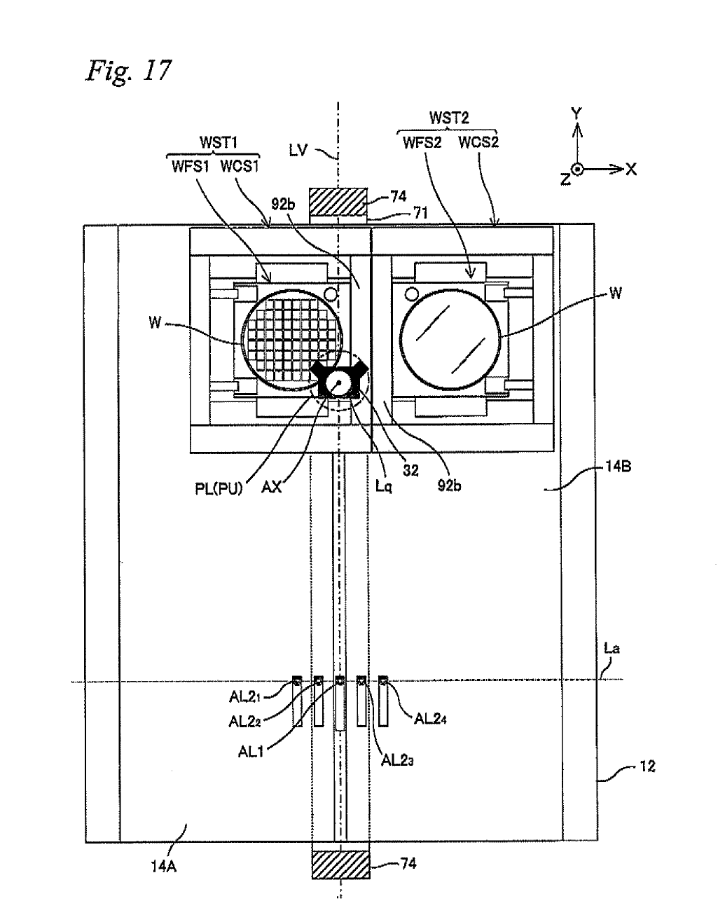

When the exposure on wafer W on fine movement stage WFS1 has been completed, main controller 20 starts to drive wafer stages WST1 and WST2 severally toward a right-side scrum position shown in FIG. 17. When wafer stage WST1 is driven in the −X direction toward the right-side scrum position, fine movement stage WFS1 moves out of the measurable range of fine movement stage position measuring system 70 (encoders 51, 52 and 53 and surface position measuring system 54) (i.e. the measurement beams irradiated from first measurement head group 72 move off from grating RG). Therefore, based on the measurement values of fine movement stage position measuring system 70 (encoders 51, 52 and 53) and the measurement values of relative position measuring system 66A, main controller 20 obtains the position of coarse movement stage WCS1, and afterward, controls the position of wafer stage WST1 based on the measurement values of coarse movement stage position measuring system 68A. More specifically, main controller 20 switches position measurement of wafer stage WST1 within the XY plane from the measurement using encoders 51, 52 and 53 to the measurement using coarse movement stage position measuring system 66A. During this operation, main controller 20 measures the position of wafer stage WST2 using coarse movement stage position measuring system 68B, and based on the measurement result, drives wafer stage WST2 in the +Y direction (refer to an outlined arrow in FIG. 16) on surface plate 14B, as shown in FIG. 16. By the action of a reaction force of this drive force of wafer stage WST2, surface plate 14B functions as the countermass.

Further, in parallel with the movement of wafer stages WST1 and WST2 toward the right-side scrum position described above, main controller 20 drives fine movement stage WFS1 in the +X direction based on the measurement values of relative position measuring system 66A and causes fine movement stage WFS1 to be in proximity to or in contact with coarse movement stage WCS1, and also drives fine movement stage WFS2 in the −X direction based on the measurement values of relative position measuring system 66B and causes fine movement stage WFS2 to be in proximity to or in contact with coarse movement stage WCS2.

Then, in a state where both wafer stages WST1 and WST2 have moved to the right-side scrum position, wafer stage WST1 and wafer stage WST2 go into a scrum state of being in proximity or in contact in the X-axis direction, as shown in FIG. 17. Simultaneously with this state, fine movement stage WFS1 and coarse movement stage WCS1 go into a scrum state, and coarse movement stage WCS2 and fine movement stage WFS2 go into a scrum state. Then, the upper surfaces of fine movement stage WFS1, coupling member 92b of coarse movement stage WCS1, coupling member 92b of coarse movement stage WCS2 and fine movement stage WFS2 form a fully flat surface that appears to be integrated.

As wafer stages WST1 and WST2 move in the −X direction while the three scrum states described above are kept, the liquid immersion area (liquid Lq) formed between tip lens 191 and fine movement stage WFS1 sequentially moves onto (is delivered to) fine movement stage WFS1, coupling member 92b of coarse movement stage WCS1, coupling member 92b of coarse movement stage WCS2, and fine movement stage WFS2. FIG. 17 shows a state just before starting the movement (delivery) of the liquid immersion area (liquid Lq). Note that in the case where wafer stage WST1 and wafer stage WST2 are driven while the above-described three scrum states are kept, it is preferable that a gap (clearance) between wafer stage WST1 and wafer stage WST2, a gap (clearance) between fine movement stage WFS1 and coarse movement stage WCS1 and a gap (clearance) between coarse movement stage WCS2 and fine movement stage WFS2 are set such that leakage of liquid Lq is prevented or restrained. In this case, the proximity includes the case where the gap (clearance) between the two members in the scrum state is zero, or more specifically, the case where both the members are in contact.

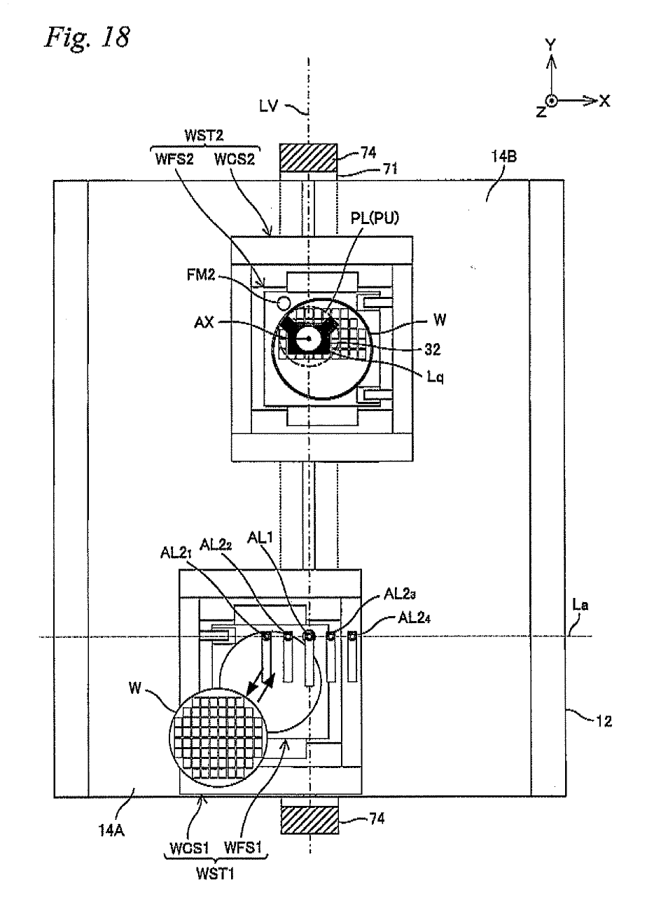

When the movement of the liquid immersion area (liquid Lq) onto fine movement stage WFS2 has been completed, wafer stage WST1 has moved onto surface plate 14A. Then, main controller 20 moves wafer stage WST1 in the −Y direction and further in the +X direction on surface plate 14A, while measuring the position of wafer stage WST1 using coarse movement stage position measuring system 68A, so as to move wafer stage WST1 to the first loading position shown in FIG. 18. In this case, on the movement of wafer stage WST1 in the −Y direction, surface plate 14A functions as the countermass owing to the action of a reaction force of the drive force. Further, when wafer stage WST1 moves in the +X direction, surface plate 14A can be made to function as the countermass owing to the action of a reaction force of the drive force.

After wafer stage WST1 has reached the first loading position, main controller 20 switches position measurement of wafer stage WST1 within the XY plane from the measurement using coarse movement stage position measuring system 68A to the measurement using encoders 55, 56 and 57.

In parallel with the movement of wafer stage WST1 described above, main controller 20 drives wafer stage WST2 and sets the position of measurement plate FM2 at a position directly under projection optical system PL. Prior to this operation, main controller 20 has switched position measurement of wafer stage WST2 within the XY plane from the measurement using coarse movement stage position measuring system 68B to the measurement using encoders 51, 52 and 53. Then, the pair of first fiducial marks on measurement plate FM2 are detected using reticle alignment systems RA₁ and RA₂ and the relative position of projected images, on the wafer, of the reticle alignment marks on reticle R that correspond to the first fiducial marks are detected. Note that this detection is performed via projection optical system PL and liquid Lq that forms the liquid immersion area.

Based on the relative positional information detected as above and the positional information of each of the shot areas on wafer W with the second fiducial mark on fine movement stage WFS2 serving as a reference that has been previously obtained, main controller 20 computes the relative positional relation between the projection position of the pattern of reticle R (the projection center of projection optical system PL) and each of the shot areas on wafer W mounted on fine movement stage WFS2. While controlling the position of fine movement stage WFS2 (wafer stage WST2) based on the computation results, main controller 20 transfers the pattern of reticle R onto each shot area on wafer W mounted on fine movement stage WFS2 by a step-and-scan method, which is similar to the case of wafer W mounted on fine movement stage WFS1 described earlier. FIG. 18 shows a state where the pattern of reticle R is transferred onto each shot area on wafer W in this manner.

In parallel with the above-described exposure operation on wafer W on fine movement stage WFS2, main controller 20 performs the wafer exchange between the wafer carrier mechanism (not illustrated) and wafer stage WST1 at the first loading position and mounts a new wafer W on fine movement stage WFS1. In this case, the first loading position is a position where the wafer exchange is performed on wafer stage WST1, and in the present embodiment, the first loading position is to be set at the position where fine movement stage WFS1 (wafer stage WST1) is located such that measurement plate FM1 is positioned directly under primary alignment system AL1.

Then, main controller 20 detects the second fiducial mark on measurement plate FM1 using primary alignment system AL1. Note that, prior to the detection of the second fiducial mark, main controller 20 executes reset (resetting of the origin) of second measurement head group 73 of fine movement stage position measuring system 70, or more specifically, encoders 55, 56 and 57 (and surface position measuring system 58), in a state where wafer stage WST1 is located at the first loading position. After that, main controller 20 performs wafer alignment (EGA) using alignment systems AL1 and AL2₁ to AL2₄, which is similar to the above-described one, with respect to wafer W on fine movement stage WFS1, while controlling the position of wafer stage WST1.

When the wafer alignment (EGA) with respect to wafer W on fine movement stage WFS1 has been completed and also the exposure on wafer W on fine movement stage WFS2 has been completed, main controller 20 drives wafer stages WST1 and WST2 toward a left-side scrum position. This left side scrum position refers to a positional relation in which wafer stages WST1 and WST2 are located at positions symmetrical to the right side scrum position shown in FIG. 17, with respect to reference axis LV previously described. Measurement of the position of wafer stage WST1 during the drive toward the left-side scrum position is performed in a similar procedure to that of the position measurement of wafer stage WST2 described earlier.

At this left-side scrum position as well, wafer stage WST1 and wafer stage WST2 go into the scrum state described earlier, and concurrently with this state, fine movement stage WFS1 and coarse movement stage WCS1 go into the scrum state and coarse movement stage WCS2 and fine movement stage WFS2 go into the scrum state. Then, the upper surfaces of fine movement stage WFS1, coupling member 92b of coarse movement stage WCS1, coupling member 921, of coarse movement stage WCS2 and fine movement stage WFS2 form a fully flat surface that appears to be integrated.

Main controller 20 drives wafer stages WST1 and WST2 in the +X direction that is reverse to the previous direction, while keeping the three scrum states described above. According this drive, the liquid immersion area (liquid Lq) formed between tip lens 191 and fine movement stage WFS2 sequentially moves onto fine movement stage WFS2, coupling member 92b of coarse movement stage WCS2, coupling member 92b of coarse movement stage WCS1 and fine movement stage WFS1, which is reverse to the previously described order. As a matter of course, also when the wafer stages are moved while the scrum states are kept, the position measurement of wafer stages WST1 and WST2 is performed, similarly to the previously described case. When the movement of the liquid immersion area (liquid Lq) has been completed, main controller 20 starts exposure on wafer W on wafer stage WST1 in the procedure similar to the previously described procedure. In parallel with this exposure operation, main controller 20 drives wafer stage WST2 toward the second loading position in a manner similar to the previously described manner, exchanges wafer W that has been exposed on wafer stage WST2 with a new wafer W, and executes the wafer alignment with respect to the new wafer W.

After that, main controller 20 repeatedly executes the parallel processing operations using wafer stages WST1 and WST2 described above.

As described above, according to exposure apparatus 100 of the embodiment, fine movement stage WFS1 (or WFS2) is supported in a non-contact manner on a surface parallel to the XY plane by fine movement stage driving systems 64A and 64B, or more precisely by the first driving section 164a and the second driving section 164b that configure a part of fine movement stage driving systems 64A and 64B, respectively, so that fine movement stage WFS1 (or WFS2) is relatively movable with respect to coarse movement stage WCS1 (or WCS2). And, by the first driving section 164a and the second driving section 164b, driving forces in directions of six degrees of freedom (X, Y, Z, θx, θy and θz) are applied to one end and the other end in the Y-axis direction of fine movement stage WFS1 (or WFS2), respectively. Magnitude and generation direction of the drive force in each of the directions are controlled independently by main controller 20, by controlling the magnitude and/or the direction of the current supplied to each of the coils in coil units 98a₁, 98a₂, 98b₁, and 98b₂ previously described. Accordingly, not only can fine movement stage WFS1 (or WFS2) be driven in directions of six degrees of freedom, by the first and second driving sections, by making the first driving section 164a and the second driving section 164b apply drive forces simultaneously in directions opposite to each other in the θx direction to one end and the other end of fine movement stage WFS1 or WFS2) in the Y-axis direction, fine movement stage WFS1 (or WFS2) (and wafer W held by the stage) can be deformed to a concave shape or a convex shape within a plane (a YZ plane) perpendicular to the X-axis. In other words, in the case when fine movement stage WFS1 (or WFS2) (and wafer W which is held by the stage) is deformed by its own weight and the like, it becomes possible to suppress this deformation.

Further, in exposure apparatus 100 of the embodiment, by measuring the position (and the tilt) in the Z-axis direction of the wafer W surface using, for example, focus sensor AF, and deforming fine movement stage WFS1 (or WFS2) in the manner described above, based on the measurement results during the exposure operation via fine movement stage driving system 64A (or 64B), the position (and the tilt) of wafer W in the optical axis direction of projection optical system PL can be controlled (focus leveling control).

Further, in exposure apparatus 100 of the embodiment, during the exposure operation and during the wafer alignment (mainly, during the measurement of the alignment marks), first measurement head group 72 and second measurement head group 73 fixed to measurement bar 71 are respectively used in the measurement of the positional information (the positional information within the XY plane and the surface position information) of fine movement stage WFS1 (or WFS2) that holds wafer W. And, since encoder heads 75x, 75ya and 75yb and Z heads 76a to 76e that configure first measurement head group 72, and encoder heads 77x, 77ya and 77yb and Z heads 78a to 78c that configure second measurement head group 73 can respectively irradiate grating RG placed on the bottom surface of fine movement stage WFS1 (or WFS2) with measurement beams from directly below at the shortest distance, measurement error caused by temperature fluctuation of the surrounding atmosphere of wafer stage WST1 and WST2, e.g., air fluctuation is reduced, and high-precision measurement of the positional information of fine movement stage WFS1 and WFS2 can be performed.

Further, first measurement head group 72 measures the positional information within the XY plane and the surface position information of fine movement stage WFS1 (or WFS2) at the point that substantially coincides with the exposure position that is the center of exposure area IA on wafer W, and second measurement head group 73 measures the positional information within the XY plane and the surface position information of fine movement stage WFS2 (or WFS1) at the point that substantially coincides with the center of the detection area of primary alignment system AL1. Consequently, occurrence of the so-called Abbe error caused by the positional error within the XY plane between the measurement point and the exposure position is restrained, and also in this regard, high-precision measurement of the positional information of fine movement stage WFS1 or WFS2 can be performed.

Further, since measurement bar 71 that has first measurement head group 72 and second measurement head group 73 is fixed in a suspended state to main frame BD to which barrel 40 is fixed, it becomes possible to perform high-precision position control of wafer stage WST1 (or WST2) with the optical axis of projection optical system PL held by barrel 40 serving as a reference. Further, since measurement bar 71 is in a noncontact state with the members (e.g. surface plates 14A and 14B, base board 14, and the like) other than main frame BD, vibration or the like generated when surface plates 14A and 14B, wafer stages WST1 and WST2, and the like are driven does not travel. Consequently, it becomes possible to perform high-precision measurement of the positional information of wafer stage WST1 (or WST2), by using first measurement head group 72 and second measurement head group 73.

Further, according to exposure apparatus 100 of the embodiment, main controller 20 can drive fine movement stages WFS1 and WFS2 with good precision, based on highly precise measurement results of positional information of fine movement stages WFS1 and WFS2. Accordingly, main controller 20 can drive wafer W mounted on fine movement stages WFS1 and WFS2 in sync with reticle stage RST (reticle R) with good precision, and can transfer a pattern of reticle R on wafer W with good precision by scanning exposure.

Further, in wafer stages WST1 and WST2 in the present embodiment, since coarse movement stage WCS1 (or WCS2) is placed on the periphery of fine movement stage WFS1 (or WFS2) wafer stages WST1 and WST2 can be reduced in size in the height direction (Z-axis direction), compared with a wafer stage that has a coarse/fine movement configuration in which a fine movement stage is mounted on a coarse movement stage. Therefore, the distance in the Z-axis direction between the point of action of the thrust of the planar motors that configure coarse movement stage driving systems 62A and 62B (i.e. the point between the bottom surface of coarse movement stage WCS1 (WCS2) and the upper surfaces of surface plates 14A and 14B) and the center of gravity of wafer stages WST1 and WST2 can be decreased, and accordingly, the pitching moment (or the rolling moment) generated when wafer stages WST1 and WTS2 are driven can be reduced. Consequently, the operations of wafer stages WST1 and WST2 become stable.

Further, in exposure apparatus 100 of the embodiment, the surface plate that forms the guide surface used when wafer stages WST1 and WST2 move along the XY plane is configured of the two surface plates 14A and 14B so as to correspond to the two wafer stages WST1 and WST2. These two surface plates 14A and 14B independently function as the countermasses when wafer stages WST1 and WST2 are driven by the planar motors (coarse movement stage driving systems 62A and 62B), and therefore, for example, even when wafer stage WST1 and wafer stage WST2 are respectively driven in directions opposite to each other in the Y-axis direction on surface plates 14A and 14B, surface plates 14A and 14B can individually cancel the reaction forces respectively acting on the surface plates.

Incidentally, while the exposure apparatus of the embodiment above has the two surface plates corresponding to the two wafer stages, the number of the surface plates is not limited thereto, and one surface plate or three or more surface plates can be employed. Further, the number of the wafer stages is not limited to two, but one wafer stage or three or more wafer stages can be employed, and a measurement stage, for example, which has an aerial image measuring instrument, an uneven illuminance measuring instrument, an illuminance monitor, a wavefront aberration measuring instrument and the like, can be placed on the surface plate, which is disclosed in, for example, U.S. Patent Application Publication No. 2007/201010.

Further, the position of the border line that separates the surface plate or the base member into a plurality of sections is not limited to the position as in the embodiment above. While the border line is set as the line that includes reference axis LV and intersects optical axis AX in the embodiments above, the border line can be set at another position, for example, in the case where, if the boundary is located in the exposure station, the thrust of the planar motor at the portion where the boundary is located weakens.

Further, the motor to drive surface plates 14A and 14B on base board 12 is not limited to the planar motor by the electromagnetic force (Lorentz force) drive method, but for example, can be a planar motor (or a linear motor) by a variable magnetoresistance drive method. Further, the motor is not limited to the planar motor, but can be a voice coil motor that includes a mover fixed to the side surface of the surface plate and a stator fixed to the base board. Further, the surface plates can be supported on the base board via the empty-weight canceller as disclosed in, for example, U.S. Patent Application Publication No. 2007/0201010 and the like. Further, the drive directions of the surface plates are not limited to the directions of three degrees of freedom, but for example, can be the directions of six degrees of freedom, only the Y-axis direction, or only the XY two-axial directions. In this case, the surface plates can be levitated above the base board by static gas bearings (e.g. air bearings) or the like. Further, in the case where the movement direction of the surface plates can be only the Y-axis direction, the surface plates can be mounted on, for example, a Y guide member arranged extending in the Y-axis direction so as to be movable in the Y-axis direction.

Further, in the embodiment above, while the grating is placed on the lower surface of the fine movement stage, i.e., the surface that is opposed to the upper surface of the surface plate, the placement is not limited to this, and the main section of the fine movement stage is made up of a solid member that can transmit light, and the grating can be placed on the upper surface of the main section. In this case, since the distance between the wafer and the grating is closer compared with the embodiment above, the Abbe error, which is caused by the difference in the Z-axis direction between the surface subject to exposure of the wafer that includes the exposure point and the reference surface (the placement surface of the grating) of position measurement of the fine movement stage by encoders 51, 52 and 53, can be reduced. Further, the grating can be formed on the back surface of the wafer holder. In this case, even if the wafer holder expands or the attachment position with respect to the fine movement stage shifts during exposure, the position of the wafer holder (wafer) can be measured according to the expansion or the shift.

Further, in the embodiment above, while the case has been described as an example where the encoder system is equipped with the X head and the pair of Y heads, the arrangement is not limited to this, and for example, one or two two-dimensional heads) (2D head (s)) whose measurement directions are the two directions that are the X-axis direction and the Y-axis direction can be placed inside the measurement bar. In the case of arranging the two 2D heads, their detection points can be set at the two points that are spaced apart in the X-axis direction at the same distance from the exposure position as the center, on the grating. In the embodiment above, while the number of the heads is one X head and two Y heads, the number of the heads can further be increased. Further, in the embodiment above, while the number of the heads per head group is one X head and two Y heads, the number of the heads can further be increased. Moreover, first measurement head group 72 on the exposure station 300 side can further have a plurality of head groups. For example, on each of the sides (the four directions that are the +X, +Y, −X and −Y directions) on the periphery of the head group placed at the position corresponding to the exposure position (a shot area being exposed on wafer W), another head group can be arranged. And, the position of the fine movement stage (wafer W) just before exposure of the shot area can be measured in a so-called read-ahead manner. Further, the configuration of the encoder system that configures fine movement stage position measuring system 70 is not limited to the one in the embodiment above and an arbitrary configuration can be employed. For example, a 3D head can also be used that is capable of measuring the positional information in each direction of the X-axis, the Y-axis and the Z-axis.

Further, in the embodiment above, the measurement beams emitted from the encoder heads and the measurement beams emitted from the Z heads are irradiated on the gratings of the fine movement stages via a gap between the two surface plates or the light-transmitting section formed at each of the surface plates. In this case, as the light-transmitting section, holes each of which is slightly larger than a beam diameter of each of the measurement beams are formed at each of surface plates 14A and 14B taking the movement range of surface plate 14A or 14B as the countermass into consideration, and the measurement beams can be made to pass through these multiple opening sections. Further, for example, it is also possible that pencil-type heads are used as the respective encoder heads and the respective Z heads, and opening sections in which these heads are inserted are formed at each of the surface plates.

Incidentally, in the embodiment above, the case has been described as an example where according to employment of the planar motors as coarse movement stage driving systems 62A and 62B that drive wafer stages WST1 and WST2, the guide surface (the surface that generates the force in the Z-axis direction) used on the movement of wafer stages WST1 and WST2 along the XY plane is formed by surface plates 14A and 14B that have the stator sections of the planar motors. However, the embodiment above is not limited thereto. Further, in the embodiment above, while the measurement surface (grating RG) is arranged on fine movement stages WFS1 and WFS2 and first measurement head group 72 (and second measurement head group 73) composed of the encoder heads (and the Z heads) is arranged at measurement bar 71, the embodiment above is not limited thereto. More specifically, reversely to the above-described case, the encoder heads (and the Z heads) can be arranged at fine movement stage WFS1 and the measurement surface (grating RG) can be formed on the measurement bar 71 side. Such a reverse placement can be applied to a stage device that has a configuration in which a magnetic levitated stage is combined with a so-called H-type stage, which is employed in, for example, an electron beam exposure apparatus, an EUV exposure apparatus or the like. In this stage device, since a stage is supported by a guide bar, a scale bar (which corresponds to the measurement bar on the surface of which a diffraction grating is formed) is placed below the stage so as to be opposed to the stage, and at least a part (such as an optical system) of an encoder head is placed on the lower surface of the stage that is opposed to the scale bar. In this case, the guide bar configures the guide surface forming member. As a matter of course, another configuration can also be employed. The place where grating RG is arranged on the measurement bar 71 side can be, for example, measurement bar 71, or a plate of a nonmagnetic material or the like that is arranged on the entire surface or at least one surface on surface plate 14A (14B).

Further, the mid portion (which can be arranged at a plurality of positions) in the longitudinal direction of measurement bar 71 can be supported on the base board by an empty-weight canceller as disclosed in, for example, U.S. Patent Application Publication No. 2007/0201010.

Incidentally, in the embodiment above, since measurement bar 71 is integrally fixed to main frame BD, there is a possibility that twist or the like occurs in measurement bar 71 owing to inner stress (including thermal stress) and the relative position between measurement bar 71 and main frame BD varies. Therefore, as the countermeasure taken in such as case, it is also possible that the position of measurement bar 71 (the relative position with respect to main frame BD, or the variation of the position with respect to a reference position) is measured, and the position of measurement bar 71 is finely adjusted by an actuator or the like, or the measurement result is corrected.

Further, in the embodiment above, while the case has been described where measurement bar 71 and main frame BD are integrated, this arrangement is not limited, and measurement bar 71 and main frame BD can physically be separated. In such a case, a measurement device (e.g. an encoder and/or an interferometer, or the like) that measures the position (or displacement) of measurement bar 71 with respect to main frame BD (or a reference position), and an actuator or the like that adjusts the position of measurement bar 71 should be arranged, and based on the measurement result of the measurement device, main controller 20 and/or another controller should maintain the positional relation between main frame BD (and projection optical system n) and measurement bar 71 in a predetermined relation (e.g. constant).

Further, a measuring system (sensor) that measures variation of measurement bar 71 with an optical method, a temperature sensor, a pressure sensor, an acceleration sensor for vibration measurement, and the like can be arranged at measurement bar 71. Or, a distortion sensor (distortion gauge), or a displacement sensor and the like to measure variation of measurement bar 71 can be arranged. Then, it is also possible to correct the positional information obtained by fine movement stage position measuring system 70 and/or coarse movement stage position measuring systems 68A and 68B, using the values obtained by these sensors.

Further, in the embodiment above, the case has been described where the liquid immersion area (liquid Lq) is constantly maintained below projection optical system PL by delivering the liquid immersion area (liquid Lq) between fine movement stage WFS1 and fine movement stage WFS2 via coupling members 92b that coarse movement stages WCS1 and WCS2 are respectively equipped with. However, the arrangement is not limited to this, and it is also possible that the liquid immersion area (liquid Lq) is constantly maintained below projection optical system PL by moving a shutter member (not illustrated) having a configuration similar to the one disclosed in, for example, the third embodiment of U.S. Patent Application Publication No. 2004/0211920, to below projection optical system PL in exchange of wafer stages WST1 and WST2.

Further, while the case has been described where the embodiment above is applied to stage device (wafer stages) 50 of the exposure apparatus, the arrangement is not limited to this, and the embodiment above can also be applied to reticle stage RST. Incidentally, in the embodiment above, grating RG can be covered with a protective member, e.g. a cover glass, so as to be protected. The cover glass can be arranged to cover the substantially entire surface of the lower surface of main section 80, or can be arranged to cover only a part of the lower surface of main section 80 that includes grating RG. Further, while a plate-shaped protective member is desirable because the thickness enough to protect grating RG is required, a thin film-shaped protective member can also be used depending on the material. Besides, it is also possible that a transparent plate, on one surface of which grating RG is fixed or formed, has the other surface that is placed in contact with or in proximity to the back surface of the wafer holder and a protective member (cover glass) is arranged on the one surface side of the transparent plate, or the one surface of the transparent plate on which grating RG is fixed or formed is placed in contact with or in proximity to the back surface of the wafer holder without arranging the protective member (cover glass). Especially in the former case, grating RG can be fixed or formed on an opaque member such as ceramics instead of the transparent plate, or grating RG can be fixed or formed on the back surface of the wafer holder. In the latter case, even if the wafer holder expands or the attachment position with respect to the fine movement stage shifts during exposure, the position of the wafer holder (wafer) can be measured according to the expansion or the shift. Or, it is also possible that the wafer holder and grating RG are merely held by the conventional fine movement stage. Further, it is also possible that the wafer holder is formed by a solid glass member, and grating n is placed on the upper surface (wafer mounting surface) of the glass member. Incidentally, in the embodiment above, while the case has been described as an example where the wafer stage is a coarse/fine movement stage that is a combination of the coarse movement stage and the fine movement stage, the present invention is not limited to this. Further, in the embodiment above, while fine movement stages WFS1 and WFS2 can be driven in all the directions of six degrees of freedom, the present invention is not limited to this, and the fine movement stages should be moved at least within the two-dimensional plane parallel to the XY plane. Moreover, fine movement stages WFS1 and WFS2 can be supported in a contact manner by coarse movement stages WCS1 and WCS2. Consequently, the fine movement stage driving system to drive fine movement stage WFS1 or WFS2 with respect to coarse movement stage WCS1 or WCS2 can be a combination of a rotary motor and a ball screw (or a feed screw). Incidentally, the fine movement stage position measuring system can be configured such that the position measurement can be performed in the entire area of the movement range of the wafer stages. In such a case, the coarse movement stage position measuring systems become unnecessary. Incidentally, the wafer used in the exposure apparatus of the embodiment above can be any one of wafers with various sizes, such as a 450-mm wafer or a 300-mm wafer.

Incidentally, in the embodiment above, while the case has been described where the exposure apparatus is the liquid immersion type exposure apparatus, the present invention is not limited to this, and the embodiment above can suitably be applied to a dry type exposure apparatus that performs exposure of wafer W without liquid (water).

Incidentally, in the embodiment above, while the case has been described where the exposure apparatus is a scanning stepper, the present invention is not limited to this, and the embodiment above can also be applied to a static exposure apparatus such as a stepper. Even in the stepper or the like, occurrence of position measurement error caused by air fluctuation can be reduced to almost zero by measuring the position of a stage on which an object that is subject to exposure is mounted using an encoder. Therefore, it becomes possible to set the position of the stage with high precision based on the measurement values of the encoder, and as a consequence, high-precision transfer of a reticle pattern onto the object can be performed. Further, the embodiment above can also be applied to a reduced projection exposure apparatus by a step-and-stitch method that synthesizes a shot area and a shot area.

Further, the magnification of the projection optical system in the exposure apparatus in the embodiment above is not only a reduction system, but also can be either an equal magnifying system or a magnifying system, and the projection optical system is not only a dioptric system, but also can be either a catoptric system or a catadioptric system, and in addition, the projected image can be either an inverted image or an erected image.

Further, illumination light IL is not limited to ArF excimer laser light (with a wavelength of 193 nm), but can be ultraviolet light such as KrF excimer laser light (with a wavelength of 248 nm), or vacuum ultraviolet light such as F₂ laser light (with a wavelength of 157 nm). As disclosed in, for example, U.S. Pat. No. 7,023,610, a harmonic wave, which is obtained by amplifying a single-wavelength laser beam in the infrared or visible range emitted by a DFB semiconductor laser or fiber laser with a fiber amplifier doped with, for example, erbium (or both erbium and ytterbium), and by converting the wavelength into ultraviolet light using a nonlinear optical crystal, can also be used as vacuum ultraviolet light.

Further, in the embodiment above, illumination light IL of the exposure apparatus is not limited to the light having a wavelength more than or equal to 100 nm, and it is needless to say that the light having a wavelength less than 100 nm can be used. For example, the embodiment above can be applied to an EUV (Extreme Ultraviolet) exposure apparatus that uses an EUV light in a soft X-ray range (e.g. a wavelength range from 5 to 15 nm). In addition, the embodiment above can also be applied to an exposure apparatus that uses charged particle beams such as an electron beam or an ion beam.

Further, in the embodiment above, a light transmissive type mask (reticle) is used, which is obtained by forming a predetermined light-shielding pattern (or a phase pattern or a light-attenuation pattern) on a light-transmitting substrate, but instead of this reticle, as disclosed in, for example, U.S. Pat. No. 6,778,257, an electron mask (which is also called a variable shaped mask, an active mask or an image generator, and includes, for example, a DMD (Digital Micromirror Device) that is a type of a non-emission type image display element (spatial light modulator) or the like) on which a light-transmitting pattern, a reflection pattern, or an emission pattern is formed according to electronic data of the pattern that is to be exposed can also be used. In the case of using such a variable shaped mask, a stage on which a wafer, a glass plate or the like is mounted is scanned relative to the variable shaped mask, and therefore the equivalent effect to the embodiment above can be obtained by measuring the position of this stage using an encoder system.

Further, as disclosed in, for example, PCT International Publication No. 2001/035168, the embodiment above can also be applied to an exposure apparatus (a lithography system) in which line-and-space patterns are formed on wafer W by forming interference fringes on wafer W.

Moreover, the embodiment above can also be applied to an exposure apparatus that synthesizes two reticle patterns on a wafer via a projection optical system and substantially simultaneously performs double exposure of one shot area on the wafer by one scanning exposure, as disclosed in, for example, U.S. Pat. No. 6,611,316.

Incidentally, an object on which a pattern is to be formed (an object subject to exposure on which an energy beam is irradiated) in the embodiment above is not limited to a wafer, but may be another object such as a glass plate, a ceramic substrate, a film member, or a mask blank.

The usage of the exposure apparatus is not limited to the exposure apparatus used for manufacturing semiconductor devices, but the embodiment above can be widely applied also to, for example, an exposure apparatus for manufacturing liquid crystal display elements in which a liquid crystal display element pattern is transferred onto a rectangular glass plate, and to an exposure apparatus for manufacturing organic EL, thin-film magnetic heads, imaging devices (such as CCDs), micromachines, DNA chips or the like. Further, the embodiment above can also be applied to an exposure apparatus that transfers a circuit pattern onto a glass substrate, a silicon wafer or the like not only when producing microdevices such as semiconductor devices, but also when producing a reticle or a mask used in an exposure apparatus such as an optical exposure apparatus, an EUV exposure apparatus, an X-ray exposure apparatus, and an electron beam exposure apparatus.

Incidentally; the disclosures of all publications, the PCT International Publications, the U.S. patent application Publications and the U.S. patents that are cited in the description so far related to exposure apparatuses and the like are each incorporated herein by reference.

Electron devices such as semiconductor devices are manufactured through the following steps: a step where the function/performance design of a device is performed; a step where a reticle based on the design step is manufactured; a step where a wafer is manufactured using a silicon material; a lithography step where a pattern of a mask (the reticle) is transferred onto the wafer with the exposure apparatus (pattern formation apparatus) of the embodiment described earlier and the exposure method thereof; a development step where the exposed wafer is developed; an etching step where an exposed member of an area other than an area where resist remains is removed by etching; a resist removing step where the resist that is no longer necessary when the etching is completed is removed; a device assembly step (including a dicing process, a bonding process, and a packaging process); an inspection step; and the like. In this case, in the lithography step, the exposure method described earlier is executed using the exposure apparatus of the embodiment above and device patterns are formed on the wafer, and therefore, the devices with high integration degree can be manufactured with high productivity.

While the above-described embodiment of the present invention is the presently preferred embodiment thereof, those skilled in the art of lithography systems will readily recognize that numerous additions, modifications, and substitutions may be made to the above-described embodiment without departing from the spirit and scope thereof. It is intended that all such modifications, additions, and substitutions fall within the scope of the present invention, which is best defined by the claims appended below.

What is claimed is:

1. An exposure apparatus that exposes an object with an energy beam via an optical system supported by a first support member, the apparatus comprising:
a first movable member which holds the object and is movable along a predetermined plane including at least a first and second axis that are orthogonal to each other;
a second movable member which supports one end and the other end of the first movable member in a direction parallel to the second axis and is movable at least along the predetermined plane;
a guide surface forming member which forms a guide surface used when the first movable member moves along the predetermined plane;
a second support member which is placed apart from the guide surface forming member on a side opposite to the optical system, via the guide surface forming member, and whose positional relation with the first support member is maintained at a predetermined state;
a position measuring system which includes a first measurement member that irradiates a measurement surface parallel to the predetermined plane with a measurement beam and receives light from the measurement surface, and which obtains positional information of the first movable member within the predetermined plane based on an output of the first measurement member, the measurement surface being arranged at one of the first movable member and the second support member and at least a part of the first measurement member being arranged at the other of the first movable member and the second support member; and
a drive system which includes a first drive section which applies a drive force on the one end of the first movable member and a second drive section that applies a drive force on the other end, and drives the first movable member in one of a singly driven and integrally driven manner with the second movable member, based on positional information from the position measuring system, whereby
the first and second drive sections can apply a drive force whose magnitude and a direction of generation can each be controlled independently to the one end and the other end of the first movable member, in a direction parallel to the first axis and the second axis, a direction orthogonal to the predetermined plane, and a rotational direction around an axis parallel to the first axis.

2. The exposure apparatus according to claim 1 wherein
the first and second drive sections further applies a drive force around an axis parallel to the second axis whose magnitude and a direction of generation can each be controlled independently to the one end and the other end of the first movable member.

3. The exposure apparatus according to claim 1 wherein
the first and the second drive sections each have a coil unit including two coil rows placed alongside in a direction parallel to the second axis in one of the second movable member and the first movable member and a magnet unit including two magnet rows placed alongside in a direction parallel to the second axis in the other of the second movable member and the first movable member corresponding to the two coil rows, and the first movable member is driven in a noncontact mariner with an electromagnetic force generated by an electromagnetic interaction between the magnet unit and the coil unit.

4. The exposure apparatus according to claim 1 wherein
the position measuring system includes a first measuring system which obtains positional information within the predetermined plane and a second measuring system which measures positional information in a direction orthogonal to the predetermined plane of the first movable member in at least three points, and
the drive system drives the first movable member based on an output of the first and second measuring systems.

5. The exposure apparatus according to claim 4 wherein
the drive system controls the first and second drive sections, based on an output of the second measuring system so as to adjust a deflection of the first movable member on which the object is mounted.

6. The exposure apparatus according to claim 5 wherein
the drive system controls the first and second drive sections so as to suppress deformation of the object caused by its own weight.

7. The exposure apparatus according to claim 4, the apparatus further comprising:
a surface position measuring system which obtains a surface position information of the object held by the first movable member, wherein
the drive system controls the first and second drive sections so that an area including an irradiation area of the energy beam on the object surface mounted on the first movable member falls within the depth of focus of the optical system.

8. The exposure apparatus according to claim 1 wherein
the second support member is a beam-like member which is placed parallel to the predetermined plane.

9. The exposure apparatus according to claim 1 wherein
a grating whose periodic direction is in a direction parallel to the predetermined plane is placed on the measurement surface, and
the first measurement member includes an encoder head that irradiates the grating with the measurement beam and receives diffraction light from the grating.

10. The exposure apparatus according to claim 1 wherein
the guide surface forming member is a surface plate that is placed on the optical system side of the second support member so as to be opposed to the first movable member and that has the guide surface parallel to the predetermined plane formed on one surface on a side opposed to the first movable member.

11. The exposure apparatus according to claim 10 wherein
the surface plate has a light-transmitting section through which the measurement beam can pass.

12. The exposure apparatus according to claim 1 wherein
the measurement plane is provided in the first movable member, and
at least a part of the first measurement member is placed at the second support member.

13. The exposure apparatus according to claim 12 wherein
the object is mounted on a first surface opposed to the optical system of the first movable member, and the measurement surface is placed on a second surface on an opposite side of the first surface.

14. The exposure apparatus according to claim 12 wherein
the measurement system has one, or two or more of the first measurement members whose measurement center, which a substantial measurement axis passes through on the measurement surface, coincides with an exposure position that is a center of an irradiation area of an energy beam irradiated on the object.

15. The exposure apparatus according to claim 12, the apparatus further comprising:
a mark detecting system that detects a mark placed on the object, wherein
the measurement system further has one, or two or more second measurement members whose measurement center, which a substantial measurement axis passes through on the measurement surface, coincides with a detection center of the mark detecting system.

16. A device manufacturing method, including
exposing an object with the exposure apparatus according to claim 1; and
developing the object which has been exposed.

17. An exposure apparatus that exposes an object with an energy beam via an optical system supported by a first support member, the apparatus comprising:
a movable body that holds the object and is movable along a predetermined plane;
a second support member whose positional relation with the first support member is maintained in a predetermined state;
a movable body supporting member placed between the optical system and the second support member so as to be apart from the second support member, which supports the movable body at one end and the other end of the movable body in a direction orthogonal to a longitudinal direction of the second support member when the movable body moves along the predetermined plane;
a position measuring system which includes a first measurement member that irradiates a measurement surface parallel to the predetermined plane with a measurement beam and receives light from the measurement surface, and which obtains positional information of the movable body within the predetermined plane based on an output of the first measurement member, the measurement surface being arranged at one of the movable body and the second support member and at least a part of the first measurement member being arranged at the other of the movable body and the second support member; and
a drive system which includes a first drive section that applies a drive force on the one end of the movable body and a second drive section that applies a drive force on the other end of the movable body, and relatively drives the movable body with respect to the movable body support member, based on positional information from the position measuring system.

18. The exposure apparatus according to claim 17 wherein
the first and second drive sections applies a drive force in directions of six degrees of freedom whose magnitude and a direction of generation can each be controlled independently to the one end and the other end of the movable body.

19. The exposure apparatus according to claim 17 wherein
the movable body support member is a surface plate that is placed on the optical system side of the second support member so as to be opposed to the movable body and that has a guide surface parallel to the predetermined plane formed on one surface on a side opposing to the movable body.

20. A device manufacturing method, including
exposing an object with the exposure apparatus according to claim 17; and
developing the object which has been exposed.

21. An exposure method in which an object is exposed with an energy beam via an optical system supported by a first support member, the method comprising;
making a first movable member, which holds the object and is movable along a predetermined plane including at least a first and second axis that are orthogonal to each other, relatively drivable at one end and the other end of the first movable member in a direction parallel to the second axis, be supported by a second movable member which is movable at least along the predetermined plane;
irradiating a measurement beam on a measurement plane parallel to the predetermined plane provided on one of the first movable member and the second support member, which is placed away from a guide surface forming member that forms a guide surface when the first movable member moves along the predetermined plane on the opposite side of the optical system, with the guide surface forming member in between, and whose positional relation with the first support member is maintained at a predetermined state, and obtaining positional information at least within the predetermined plane of the first movable member, based on an output of a first measurement member which receives light from the measurement plane and has at least a part of the member provided in the other of the first movable member and the second support member; and
applying a drive force whose magnitude and a direction of generation can each be controlled independently to the one end and the other end of the first movable member, in a direction parallel to the first axis and the second axis, a direction orthogonal to the predetermined plane, and a rotational direction around an axis parallel to the first axis, based on positional information which has been obtained.

22. The exposure method according to claim 21 wherein
a drive force around an axis parallel to the second axis whose magnitude and a direction of generation can each be controlled independently is further applied to the one end and the other end of the first movable member.

23. The exposure method according to claim 21, the method further comprising:
measuring positional information of the first movable body in the direction orthogonal to the predetermined plane at least at three points, and based on the measurement results, applying a driving force in the rotational direction around the axis parallel to the first axis with respect to the one end and the other end of the first movable member, and adjusting a deflection of the first movable member on which the object is mounted.

24. The exposure method according to claim 21 wherein
a deflection of the first movable member is adjusted so as to suppress deformation of the object caused by its own weight.

25. The exposure method according to claim 22, the method further comprising;
obtaining a surface position information of the object held by the first movable member, wherein
a driving force is applied in the rotational direction around the axis parallel to the first axis with respect to the one end and the other end of the first movable member, so that an area including an irradiation area of the energy beam on the object surface mounted on the first movable member falls within the depth of focus of the optical system.

26. A device manufacturing method, including
exposing an object by the exposure method according to claim 21; and
developing the object which has been exposed.
